(19) United States
(12) Patent Application Publication
(10) Pub. No.: US 2025/0357224 A1
(43) Pub. Date: Nov. 20, 2025

(54) DEVICE PACKAGE AND MANUFACTURING METHOD THEREOF

(71) Applicant: TAIWAN SEMICONDUCTOR MANUFACTURING COMPANY, LTD., Hsinchu (TW)

(72) Inventors: Feng-Chang HSU, Hsinchu County (TW); Hsu-Hsien CHEN, Hsinchu City (TW); Pei Chun TSAI, Hsinchu City (TW); Chi-Yen LIN, Tainan City (TW); Chen-Shien CHEN, Hsinchu County (TW)

(73) Assignee: TAIWAN SEMICONDUCTOR MANUFACTURING COMPANY, LTD., Hsinchu (TW)

(21) Appl. No.: 19/291,892

(22) Filed: Aug. 6, 2025

Related U.S. Application Data
(63) Continuation of application No. 18/443,616, filed on Feb. 16, 2024.

(51) Int. Cl. H01L 21/66; H01L 21/56; H01L 23/00; H01L 23/34; H01L 25/065; H01L 25/10

(52) U.S. Cl. CPC H01L 22/34; H01L 21/568; H01L 22/14; H01L 23/34; H01L 23/562; H01L 24/05; H01L 24/08; H01L 24/80; H01L 24/97; H01L 25/105; H01L 25/0655; H01L 2224/08145; H01L 2224/80895; H01L 2224/80896; H01L 2224/80908; H01L 2224/95001; H01L 2224/97; H01L 2225/1094

(57) ABSTRACT

A method includes bonding a first semiconductor die to a first substrate, the semiconductor die comprising a second substrate and a through-substrate via (TSV) extending at least partially through the second substrate; forming a first dielectric material laterally surrounding the first semiconductor die; forming a probe pad over the first dielectric material; forming a bond pad over the TSV, the bond pad being electrically coupled to the probe pad; bonding a second semiconductor die to the first semiconductor die through the bond pad, wherein the probe pad is laterally offset from the second semiconductor die.

### PRIORITY CLAIM AND CROSS-REFERENCE

The present application is a Continuation application of the U.S. application Ser. No. 18/443,616, filed Feb. 16, 2024, which is herein incorporated by reference in its entirety.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a semiconductor structure including a monitoring circuit during a wafer acceptance testing (WAT) process at chip stacking level in accordance with some embodiments of the present disclosure.

FIG. 1B illustrates a local enlarged top view of a region C1 in FIG. 1A.

FIGS. 1C-1E illustrate cross-sectional views taken along lines B-B′ as shown in FIG. 1B.

FIGS. 1F-1I illustrate top views of a probe pad, a bumping pad, a first metal line connecting the probe pad to the bumping pad, and a second metal line electrically coupled adjacent two of the bumping pad in FIG. 1B, respectively, in accordance with some embodiments of the present disclosure.

FIGS. 2A-2E, 2G-2J and 2L-2Q illustrate cross-sectional views of intermediate stages in the formation of a package including a monitoring circuit in accordance with some embodiments of the present disclosure.

FIG. 2F illustrates a local enlarged top view of a region C2 in FIG. 2E.

FIG. 2K illustrates a local enlarged cross-sectional view of a region C3 in FIG. 2J.

FIG. 2R illustrates a cross-sectional view of a package including a monitoring circuit in accordance with some embodiments of the present disclosure.

FIG. 2S illustrates a local enlarged top view of a region C4 in FIG. 2R.

FIGS. 3A and 4A illustrate cross-sectional view of device package including at least portions of monitoring circuits corresponding to FIG. 2R in accordance with some embodiments of the present disclosure.

FIGS. 3B and 4B illustrate local enlarged top views of regions C5 and C6 in FIGS. 3A and 4A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Current advancements in System on Integrated Chips (SoIC) technology are facing challenges with hybrid bonding, particularly when bonding strength between chips is insufficient. This issue may arise in the interface between the back-side bond pad metal (BSBPM) and the bond pad metal (BPM). When the bonding strength is inadequate, it can lead to a lack of proper contact at the BPM and BSBPM interface, which affects the performance and reliability of the chips, resulting in circuit probe test (CPS) failure.

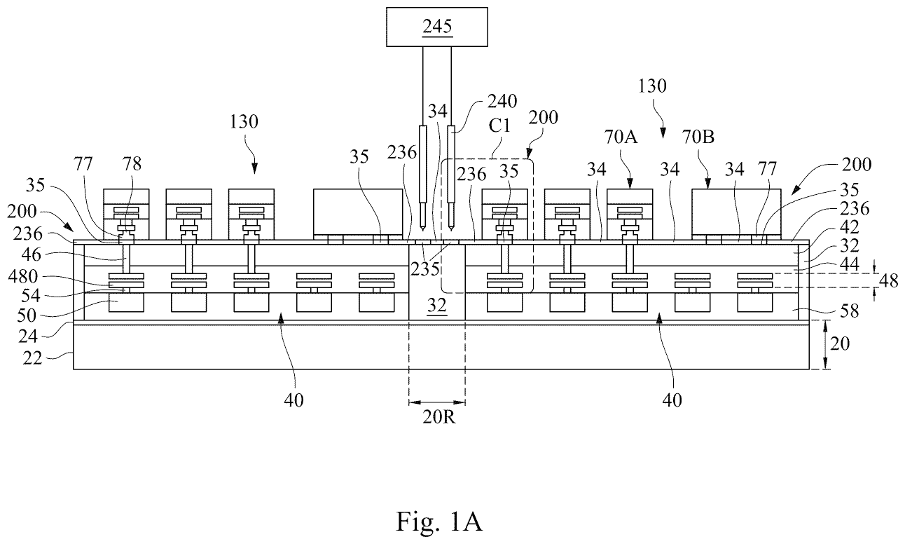

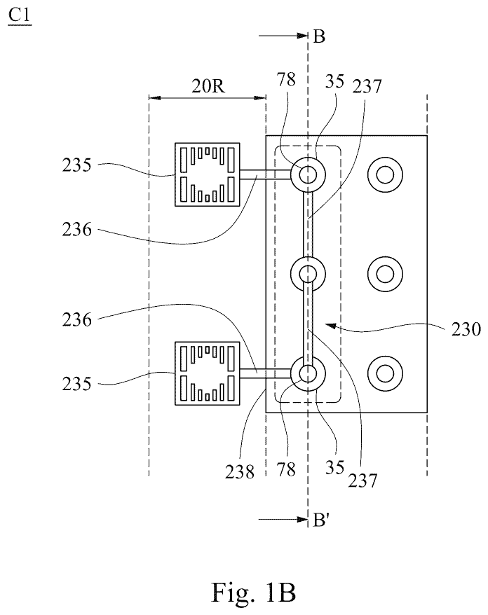

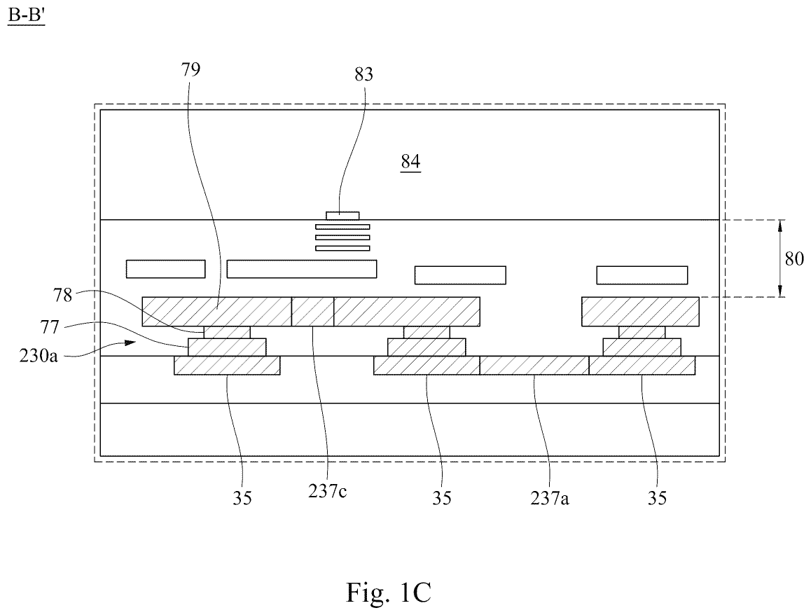

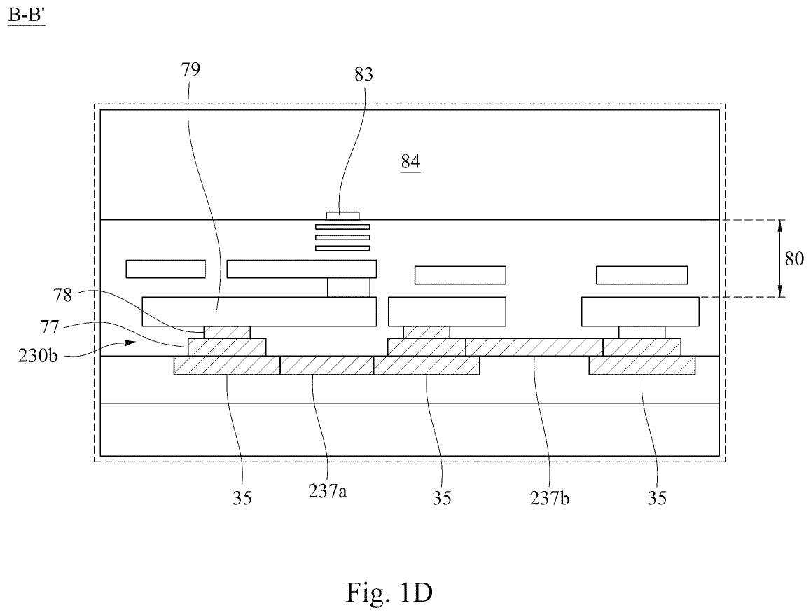

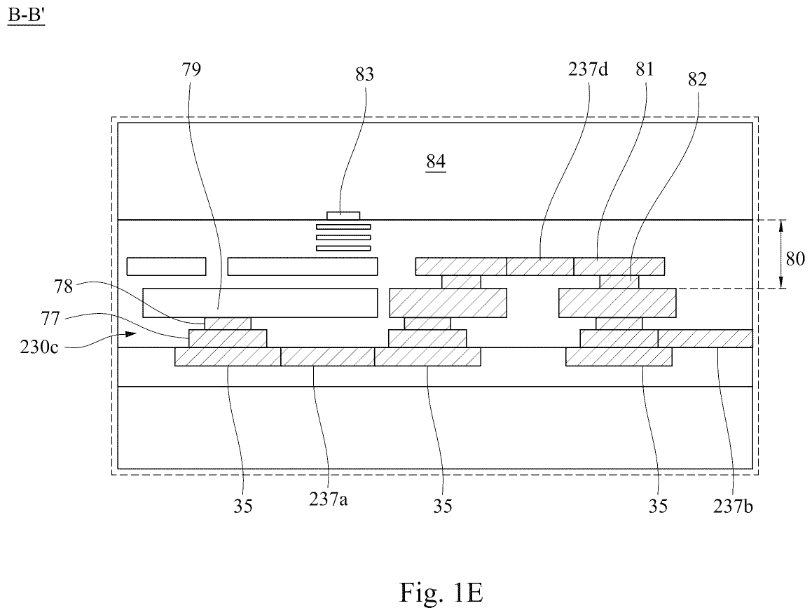

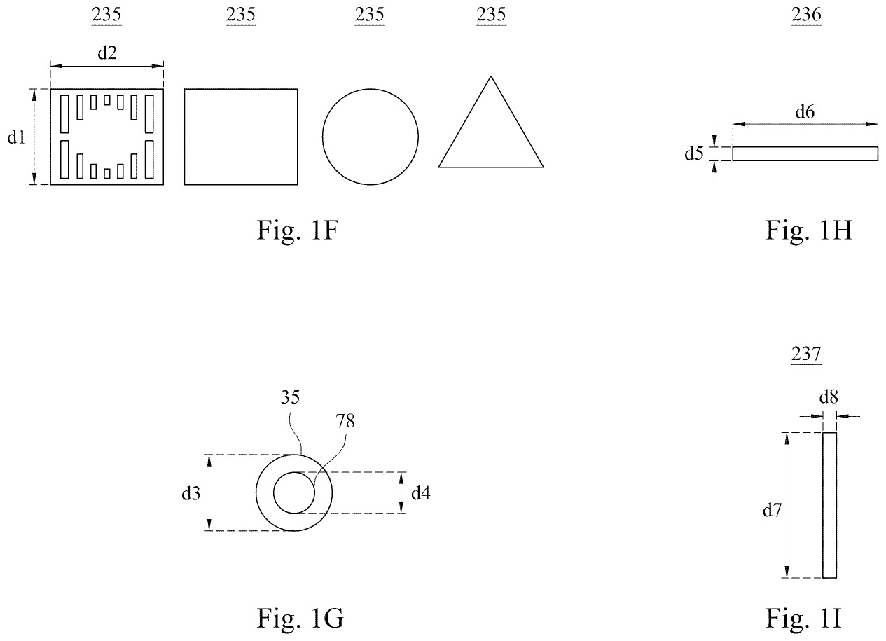

Therefore, the present disclosure in various embodiments provides a layout (e.g., monitoring circuit 200 shown in FIGS. 1A and 1B) for hybrid bonding wafer acceptance testing (WAT) design, focusing on the chip boundary and scribe line areas. This layout is for addressing the challenges of hybrid bonding in SoIC fabrication. The layout can facilitate early detection of the performance and integrity of hybrid bonding. Hybrid bonding is a process used to join two semiconductor wafers or die (e.g., package component 40 and package component 70A/70B) using a combination of metal-to-metal and dielectric-to-dielectric bonding, enabling fine-pitch interconnections. Test patterns (e.g., monitoring circuit 200) can be placed at the chip's boundaries and scribe line areas, the regions that are for ensuring the structural and functional integrity of the chip. By focusing on these areas, the design allows for early assessment of the bonding quality during the manufacturing process. This approach can help in identifying bonding issues before the chip progresses too far in the production line, thereby reducing waste and improving overall yield.

Reference is made to FIGS. 1A-1I. FIG. 1A illustrates a cross-sectional view of a semiconductor structure including a monitoring circuit 200 during a wafer acceptance testing (WAT) process at chip stacking level in accordance with some embodiments of the present disclosure. In some embodiments, the WAT process can be a circuit probe test. FIG. 1B illustrates a local enlarged top view of a region C1 in FIG. 1A. FIGS. 1C-1E illustrate cross-sectional views taken along lines B-B′ as shown in FIG. 1B. FIGS. 1F-1I illustrate top views of a circuit probe pad 235, a bond pad 35, a metal line 236 connecting the circuit probe pad 235 to the bond pad 35, and a metal line 237 electrically coupled adjacent two of the bond pad 35 in FIG. 1B, respectively, in accordance with some embodiments of the present disclosure.

As shown in FIG. 1A, the package components 70A and 70B are attached to package components 40 to form device packages 130. The package components 40 can be individual device dies (e.g., integrated circuit dies), packages having one or more device dies packaged therein, System-on-Chip (SoC) dies including a plurality of integrated circuits integrated as a system, or the like. In some embodiments, the package component 40 may include a semiconductor substrate 42 (e.g., a silicon substrate), integrated circuit devices at a front-side surface of semiconductor substrate 42, a dielectric layer 44 formed over the semiconductor substrate 42 and the integrated circuit devices, and an interconnect structure 48 formed through the dielectric layer 44. Through-substrate vias (TSVs) 46 may extend partially through semiconductor substrate 42, and may further extend partially through the dielectric layer 44. The interconnect structure 48 can include metal lines at different levels and vias electrically connected to the integrated circuit devices. The interconnect structure 48 can include a plurality of levels of the metal lines. In addition, one or more levels of upper metal lines 48U of interconnect structure 48 may be coupled to corresponding ones of TSVs 46, such as through levels of lower metal lines of interconnect structure 48.

The package components 70A and 70B may include active package components 70A and dummy package components 70B. The active package components 70A may include integrated circuits. The dummy package components 70B may be included for structural integrity and/or heat dissipation during fabrication and/or during functional use of the completed semiconductor package. Although one of the active package components 70A and one of the dummy package components 70B are illustrated as being attached to each corresponding one of the package components 40, there may be a plurality of the active package components 70A and/or a plurality of the dummy package components 70B attached to each corresponding one of the package components 40. The package components 70A/70B may be discrete package components physically separate from each other (e.g., already singulated from their respective wafers). In some embodiments, only one of the package components 70A/70B or other combinations of the package components 70A/70B may be attached to a corresponding one of the package components 40. In some embodiments, the package component 70A can be a charge coupled device (CCD) die. In some embodiments, the package component 70A, 70B, and/or the package component 40 can be interchangeable referred to as a die or a chip. In some embodiments, the package component 40 can be interchangeable referred to as a bottom tier die, and the package component 70A, 70B can be interchangeable referred to as a top tier die.

In some embodiments, poor bonding between package components, such as between package component 40 and components 70A and 70B may occur. If the surfaces of the package components 40 or the components 70A and 70B to be bonded are contaminated with particles, oils, or other residues, the bond may not form correctly, leading to weak adhesion and poor electrical contact. In some embodiments, incompatibilities of the materials of the bonding surfaces can result from differences in thermal expansion coefficients, metal reactivity, or other material properties, resulting in poor bonding. In some embodiments, deviations of the bonding process parameters such as temperature, pressure can lead to inadequate bonding, such as cold solder joints in the case of soldering or incomplete curing for adhesives, resulting in poor bonding. Therefore, after the attachment of the package components 70A and 70B, a monitoring circuit 200 can be formed as a diagnostic feature integrated into the semiconductor package to assess the quality of the bonding between the package components 40 and the package components 70A and 70B.

As shown in FIGS. 1A and 1B, the monitoring circuit 200 can include the circuit probe pads 235 over the scribe line regions 20R, the bond pads 35 over the package component 40, metal lines 236 extending from the circuit probe pads 235 to the bond pads 35, and daisy chain structures 230a-230c (see FIGS. 1C-1E) including metal lines 237. The circuit probe pads 235 can be formed over the gap-filling material 32 in the scribe line regions 20R to interface with external testing equipment (e.g., probes 240). During the circuit probe test, the probes 240 make contact with the circuit probe pads 235 to test the circuit's electrical characteristics. The bond pads 35 can be the points of electrical and physical connection to the TSVs 46 or other internal connectors within the package components 70A and 70B (e.g., bond pads 77) for creating a continuous electrical path across the different layers of the package. In FIG. 1A, the package components 70A/70B and the package components 40 with only one bond pad 35 each is a simplified example for illustrative purposes. However, in semiconductor design and manufacturing, the number of bond pads 35 on each package component can vary based on the complexity and requirements of the circuit. The metal lines 236 can serve as the conductive pathways that connect the circuit probe pads 235 to the bond pads 35 for the functionality of the circuit probe test, as they enable the transmission of electrical signals during testing. The metal lines 237 can be part of daisy chain structures 230a-230c (see FIGS. 1C-1E) within the package components 70A and 70B. Daisy chaining is a method where components are connected in series, one after another, which allows for the entire chain to be tested for continuity. Breaks or defects in the daisy chain indicate potential issues with bonding quality between the package components 40 and the package components 70A and 70B.

By integrating these components (e.g., circuit probe pads 235, bond pads 35, metal lines 236, and daisy chain structures 230 including metal lines 237), the monitoring circuit 200 can effectively determine the integrity of the bond between different package components. A circuit probe test can be performed to evaluate the quality of electrical connections between the package components 40 and the package components 70A/70B. During the circuit probe test, the probes 240 can be brought into contact with the circuit probe pads 235. The circuit probe pads 235 can be electrically connected to the structures that include the bonds between the package components 40 and the components 70A and 70B.

Specifically, when the circuit probe test is conducted, the circuit probe test can measure electrical properties such as resistance and continuity between the package components 40 and the components 70A and 70B. Deviations from expected values can indicate poor bonding, prompting further inspection or rework before additional manufacturing processes continue. The circuit probe test can ensure the reliability of the semiconductor package before it reaches later stages of production. Under good bonding conditions, the resistance should be low and within specified tolerances, indicating that the bond pads are properly connected and that there is a solid intermetallic connection. If the bonding is poor, such as due to incomplete soldering, contamination, or voids in the bond, the resistance will be higher than expected. This is because poor bonding can result in a reduced contact area or introduce defects that impede current flow. The test equipment 245 connected to the probes 240 may compare the measured resistance values against known good profiles (e.g., from a database of acceptable resistance measurements for well-bonded connections) to determine if the bond quality is within acceptable limits. In some embodiments, the circuit probe test may involve dynamic testing where resistance is measured under varying electrical loads or temperatures to assess the stability of the bond under operating conditions. A deviation from the expected resistance value would suggest a problem with the bond, triggering a need for rework or scrapping of the semiconductor structure. Therefore, by applying circuit probe tests across the semiconductor structures and interpreting the resistance data, the quality of the bonding across the entire wafer, identifying any areas of concern that need to be addressed.

By performing the circuit probe test at this stage, any defective bonding between the package components 40 and the components 70A and 70B can be identified early on. Detecting such defects before more layers and complexity are added to the package components 40 and the components 70A and 70B can avoid the additional costs that would be incurred if the defect were found after further processing. The circuit probe test involving the monitoring circuit 200 can help in verifying that the bonding quality meets the necessary standards. If the test indicates good bonding, manufacturing proceeds to the next stages. If the bonding is found to be poor, corrective measures can be taken immediately. By incorporating such early testing protocols, the semiconductor manufacturing process can become more reliable and cost-effective, as defects are caught and addressed at the earliest possible stage.

Specifically, the circuit probe pad 235 can have a same level height as the bond pads 35. In some embodiment, the circuit probe pad 235 can be formed simultaneously with the bond pad 35, and has a top surface level with a top surface of the bond pad 35. When the circuit probe pad 235 and the bond pad 35 are fabricated at the same time, they can be made from the same material. As shown in FIG. 1B, from a top view, the circuit probe pad 235 can have a first dimension d1 extending along a lengthwise direction of the scribe line region 20R and/or along an edge of the package component 40, and a second dimension d2 extending along a direction perpendicular to the lengthwise direction of the scribe line region 20R and/or along the edge of the package component 40. In some embodiments, the first dimension d1 of the circuit probe pad 235 is substantially the same as the second dimension d2 of the circuit probe pad 235. In some embodiments, the first dimension d1 of the circuit probe pad 235 can be greater than or less than the second dimension d2 of the circuit probe pad 235. By way of example and not limitation, the first dimension d1 of the circuit probe pad 235 can be greater than about 40 μm, and the second dimension d2 greater than about 40 μm. As shown in FIG. 1F, the circuit probe pads 235 can have slot top view patterns, solid rectangular top view patterns, circular top view patterns, a triangular top view pattern, other suitable patterns, or combinations thereof.

The bond pads 35 can be formed over and electrically connected with the TSVs 46. The bond pads 35 can provide a direct electrical connection between the TSVs 46 or other electrical pathways within the package components 40. In addition, the bond pads 35 can contribute to the physical bonding between different package components (e.g., package components 70A and 70B). In some embodiments, the bond pad 35 can be interchangeable referred to as a back-side bond pad metal (BSBPM). As shown in FIG. 1B, from a top view, adjacent two of the bond pads 35 can have a pitch (e.g., distance) in a range from about 1-20 μm, such as about 1, 2, 4, 6, 8, 10, 12, 14, 16, 18, or 20 μm. As shown in FIG. 1G, the bond pad 35 can have a circular top view pattern. In some embodiments, from the top view, the bond pad 35, the TSV 46, a bond pad 77, and/or a bond via 78 are concentric circles. In some embodiments, the bond pad 35 has a maximum dimension d3 (e.g., diameter) greater than a maximum dimension d4 (e.g., diameter) of the bond via 78 in the package component 70A/70B and over the bond pad 77 being in contact with the bond pad 35. In some embodiments, the maximum dimension d3 of the bond pad 35 is less than the first dimension d1 and/or the second dimension d2 of the circuit probe pad 235. By way of example and not limitation, the maximum dimension d3 of the bond pads 35 can be in a range from about 1-10 μm, such as about 1, 2, 3, 4, 5, 6, 7, 8, 9, or 10 μm. In some embodiments, the bond pad 77 can be interchangeable referred to as a bond pad metal (BPM), and the bond via 77 can be interchangeable referred to as a bond pad via (BPV).

The metal lines 236 can be formed to extend from the circuit probe pads 235 to the bond pads 35 across an interface 238 (see FIG. 1B) between the package component 40 and the gap-filling material 32. The metal lines 236 formed over the gap-filling material 32 and the back-side surface of the package component 40. In some embodiment, the metal lines 236 can be formed simultaneously with the bond pad 35, and has a top surface level with a top surface of the bond pad 35. When the metal lines 236 and the bond pad 35 are fabricated at the same time, they can be made from the same material. As shown in FIG. 1H, from the top view, the metal line 236 can have a first dimension d5 (e.g., width) extending along the lengthwise direction of the scribe line region 20R and/or along the edge of the package component 40, and a second dimension d6 (e.g., length) extending along the direction perpendicular to the lengthwise direction of the scribe line region 20R and/or along the edge of the package component 40. In some embodiments, the first dimension d5 of the metal line 236 is less than the maximum dimension d3 of the bond pad 35, the maximum dimension d4 of the bond via 78, and the first and second dimensions d1 and d2 of the circuit probe pad 235. By way of example and not limitation, the first dimension d5 of the metal line 236 can be in a range from about 1-10 μm, such as about 1, 2, 3, 4, 5, 6, 7, 8, 9, or 10 μm, and the second dimension d6 of the metal line 236 can be in a range from about 2.5-100 μm, such as about 2.5, 5, 10, 20, 30, 40, 50, 60, 70, 80, 90, or 100 μm.

The daisy chain 230 can used to ensure the quality and integrity of the bonding between different package components (e.g., between the package component 40 and the package component 70A/70B). The daisy chain 230 can serve as a circuit path between the package components 40 and the package components 70A/70B and including the bonding positions between these package components, which in turn provides a means to electrically connect the circuit probe pads 235 to these bonding positions. By incorporating the daisy chain 230 into the device package 130, it becomes possible to use circuit probe tests to check for any poor bonding in the device packages 130. The daisy chain 230 includes metal line 237 (see FIG. 1B), which forms part of the continuous path in the chain, creating a conductive link across different components in the device package 130. FIGS. 1C-1E illustrate various configurations for the daisy chain 230 in adapting to different package designs and requirements. In some implementations, the daisy chain 230, including metal line 237, may already be an integral part of the electrical signal path in package components 70A/70B. Alternatively, in some embodiments, the daisy chain 230, including metal line 237, may be specifically manufactured to serve for detecting bonding conditions. This approach can be applied when the circuit design does not inherently provide a pathway suitable for bonding quality assessment. Therefore, the daisy chain 230 can act as a diagnostic feature in the semiconductor package, allowing for the early detection of bonding issues between the package components 40 and the package components 70A/70B.

In some embodiments, the daisy chain 230 can be situated at a boundary (or edge) of the package component 70A/70B and situated at a boundary (or edge) of the package component 40. In some embodiments, the boundary areas in these package components may often where mechanical stress is concentrated during manufacturing and operation. The daisy chain 230 at the boundary can help monitor these stress points, ensuring the structural integrity of the device. Alternatively, the boundary areas may have thermal management, such that the daisy chain 230 can monitor the effectiveness of heat distribution and dissipation across the interfaces. Therefore, by ensuring interconnections at the boundaries, the daisy chain 230 can help maintain the electrical performance of the semiconductor package.

In FIGS. 1B-1E, the daisy chain circuits (e.g., daisy chains 130 and 130a-130c) incorporate multiple bonding positions that are distributed among various package components, both package components 70A/70B and 40. The arrangement and connectivity of these package components within the daisy chain are used in testing the integrity of the bonds in the semiconductor package. The daisy chain paths can encompass multiple package components 70A/70B and 40. This integration can ensure a comprehensive connectivity check across a wider area in the device package 130. The package components within the daisy chain can be arranged along the lengthwise direction and/or perpendicular to the lengthwise direction of the scribe line region 20R, allowing for maximizing the efficacy of the daisy chain in testing the integrity of connections across the wider area in the device package 130, which in turn increases the likelihood of detecting potential failures, thereby enhancing the overall reliability of the device package 130.

In some embodiments, the daisy chain (e.g. daisy chains 230a-230c shown in FIGS. 1C-1E) can incorporate a metal line 237a, which connects adjacent bond pads 35, allowing for testing the electrical connectivity and bonding quality directly on the package component 40. In some embodiments, the daisy chain (e.g. daisy chains 230b and 230c shown in FIGS. 1D and 1E) can incorporate a metal line 237b, which connects adjacent bond pads 77 on the package components 70A/70B, allowing for the assessment of bonding and electrical continuity within the active package components 70A or within the dummy package components 70B. In some embodiments, the daisy chain (e.g. daisy chain 230a shown in FIG. 1C) can incorporate a metal line 237c, which connects adjacent metal pads 79, where the metal pads 79 are situated above the bond vias 78 of the package components 70A/70B, allowing for evaluating the connectivity and bonding integrity at a level above the bond vias 78, providing insights into the upper layer connections within the package components 70A/70B. In some embodiments, the metal pad 79 may comprise aluminum, an aluminum-copper alloy, or any suitable material, and can be interchangeable referred to as an aluminum pad (AP). In some embodiments, the daisy chain (e.g. daisy chain 230c shown in FIG. 1E) can incorporate a metal line 237d, which connects adjacent top metal layers 81/metal vias 82 within the inter-dielectric layer 80 of package components 70A/70B, allowing for evaluating the connectivity and bonding integrity at higher interconnect levels within the package components 70A/70B. Therefore, the daisy chain can vary to suit different layers and components within the semiconductor package, offering flexibility in testing various aspects of electrical connectivity and bond integrity. By including these daisy chains in different configurations, the reliability and functionality of the semiconductor packages can be ensured. In FIGS. 1C-1E, a transistor device 83 can be formed on a substrate 84 and electrically connected to the bond pads 77.

As shown in FIG. 1I, from the top view, the metal line 237 can have a first dimension d7 (e.g., length) extending along the lengthwise direction of the scribe line region 20R and/or along the edge of the package component 40, and a second dimension d8 (e.g., width) extending along the direction perpendicular to the lengthwise direction of the scribe line region 20R and/or along the edge of the package component 40. In some embodiments, the second dimension d8 of the metal line 236 is less than the maximum dimension d3 of the bond pad 35, the maximum dimension d4 of the bond via 78, and the first and second dimensions d1 and d2 of the circuit probe pad 235. In some embodiments, the second dimension d8 of the metal line 237 can be greater than the first dimension d5 of the metal 236. By way of example and not limitation, the first dimension d7 of the metal line 237 can be in a range from about 2.5-100 μm, such as about 2.5, 5, 10, 20, 30, 40, 50, 60, 70, 80, 90, or 100 μm, and the second dimension d8 of the metal line 237 can be in a range from about 1-100 μm, such as about 1, 10, 20, 30, 40, 50, 60, 70, 80, 90, or 100 μm.

Referring back to FIG. 1A, metal pads 50 are disposed over the dielectric layer 44 and electrically connected to the upper metal lines 48U of the interconnect structure 48 by the conductive vias 54. Some of the metal pads 50 may be connected to the TSVs 46 by the interconnect structure 48. Some of the metal pads 50 may be connected to the integrated circuit devices at the surface of the semiconductor substrate 42 by the interconnect structure 48. A dielectric bond layer 58 may be formed over the metal pads 50 of the package component 40. The package components 40 can be attached to a carrier 20. The carrier 20 may be a substrate and includes a base carrier 22, one or more dielectric bond layers 24. In some embodiments, base carrier 22 may be a wafer and may be a similar material as the semiconductor substrate 42 in the package component 40. A gap-filling material 32 is formed over the package components 40 and the carrier 20 to encapsulate the package components 40.

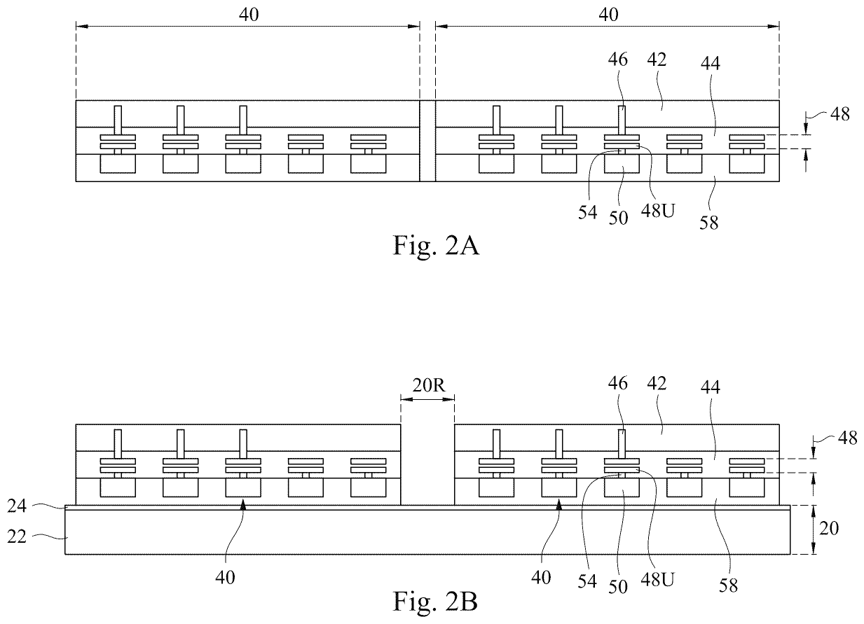

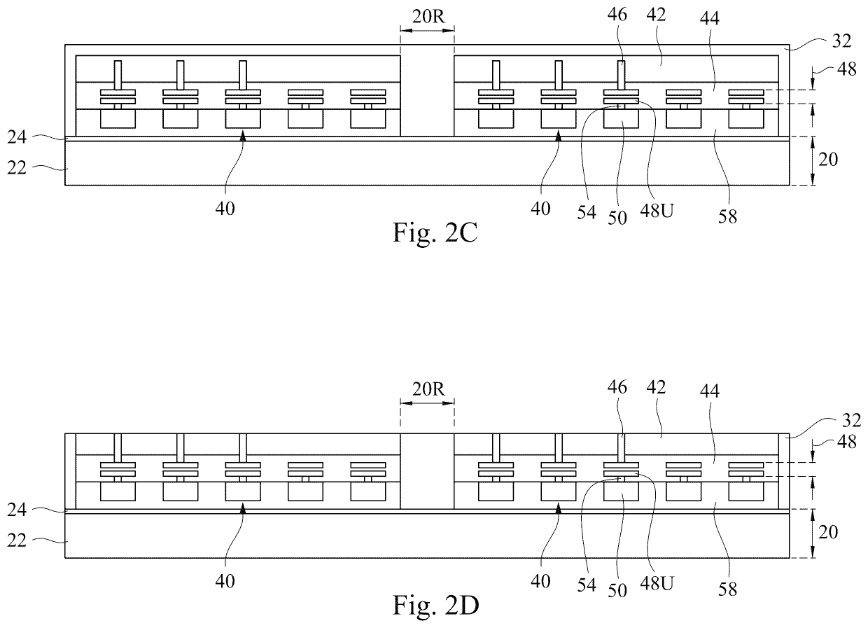

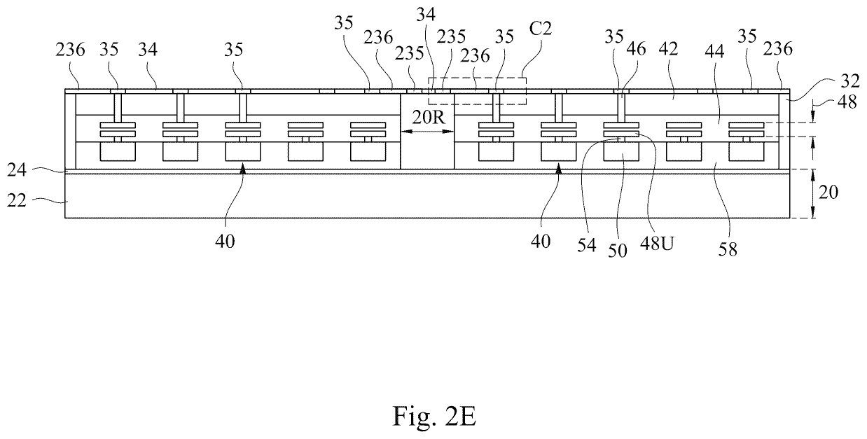

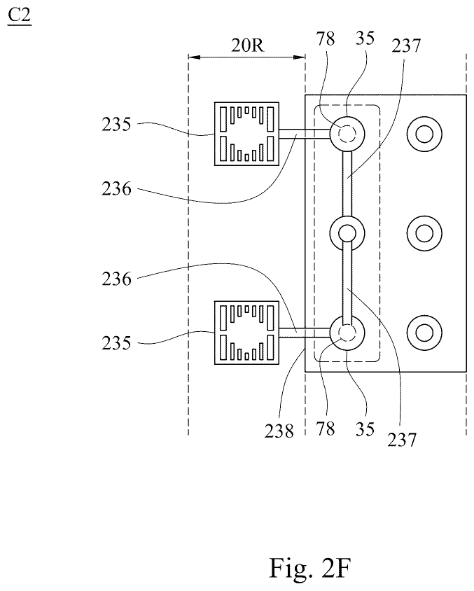

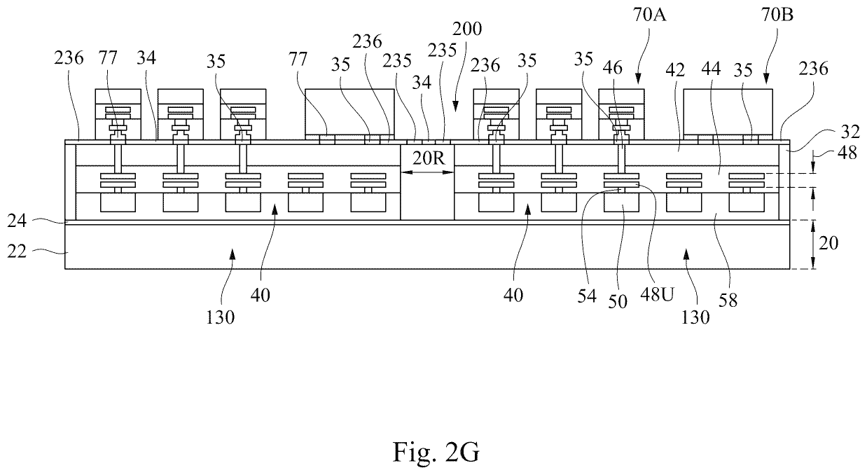

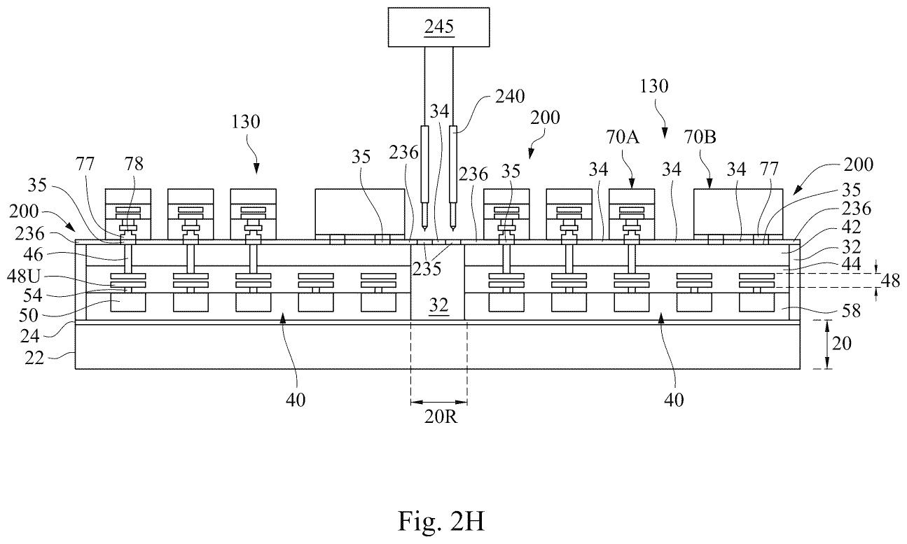

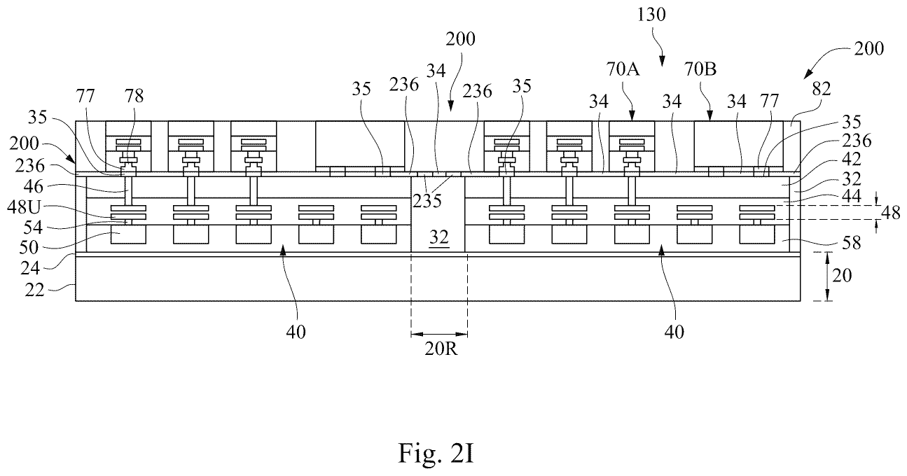

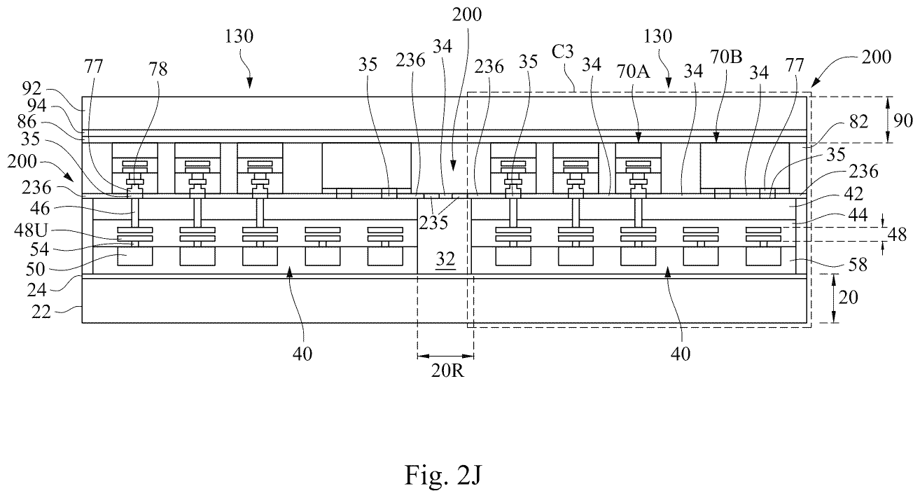

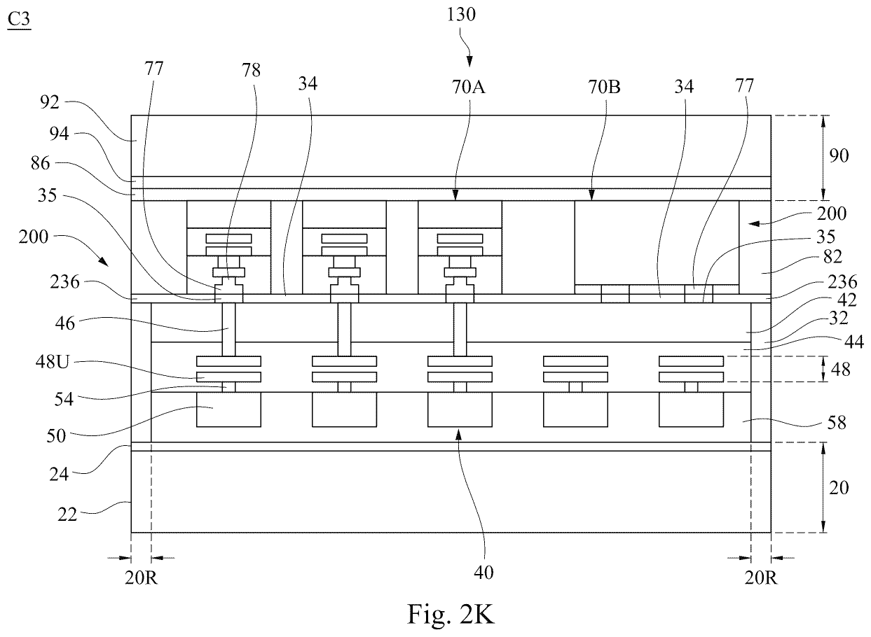

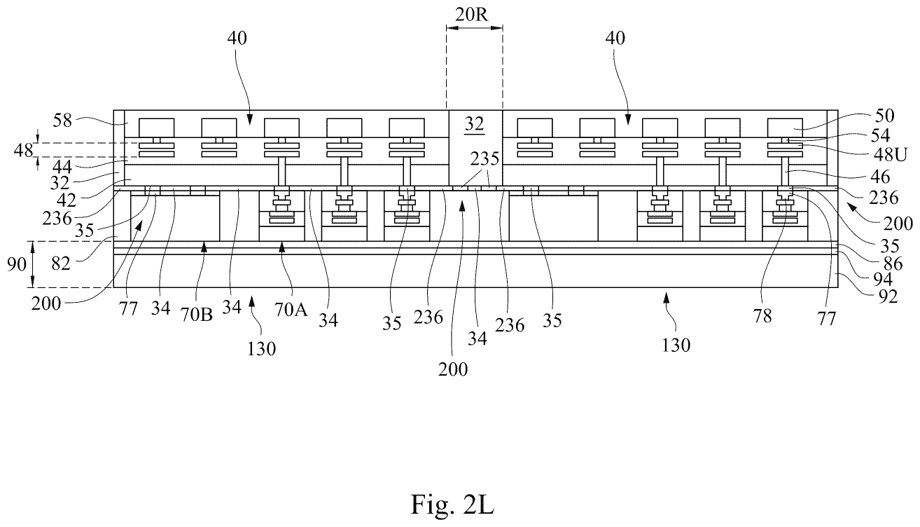

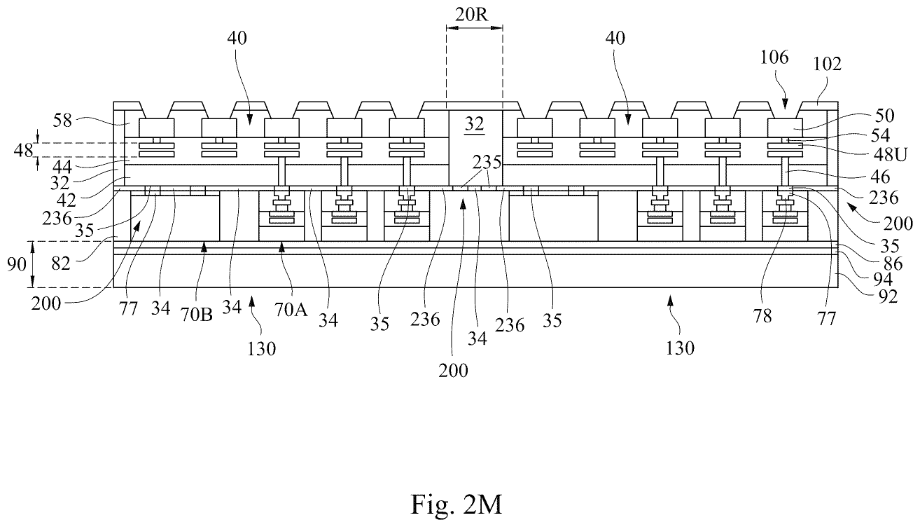

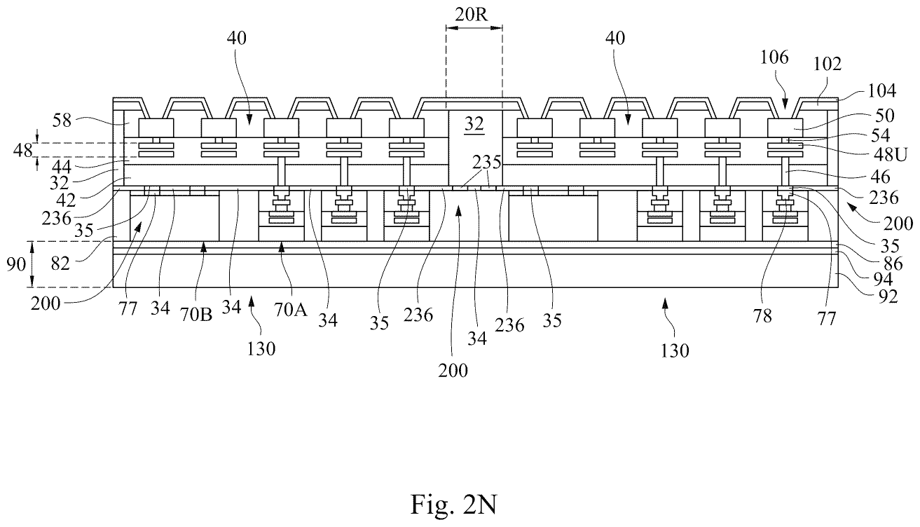

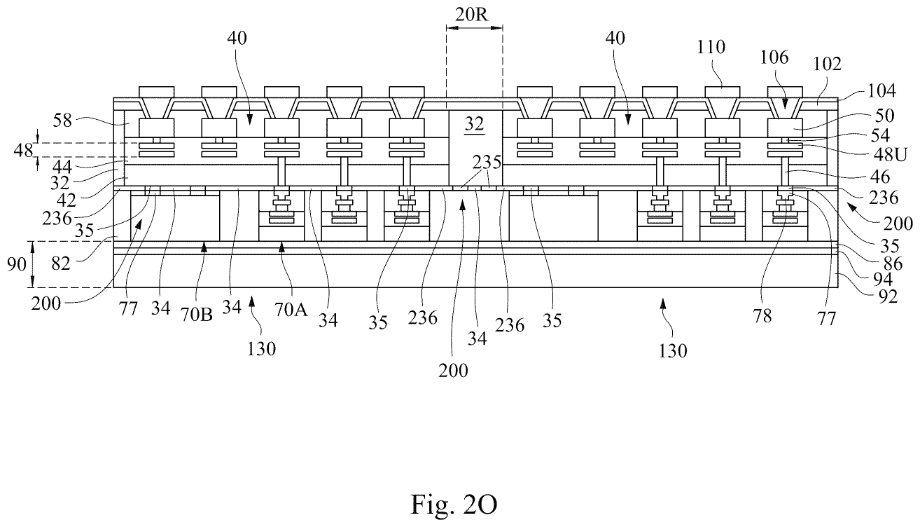

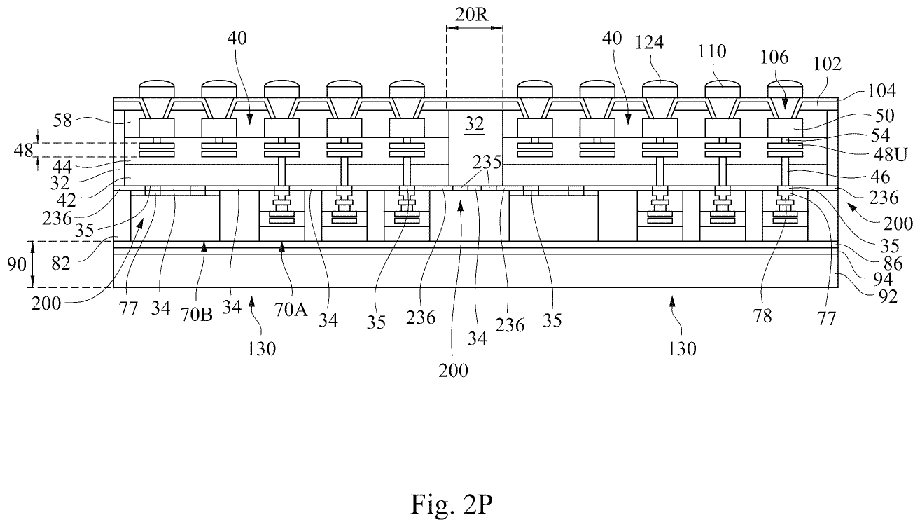

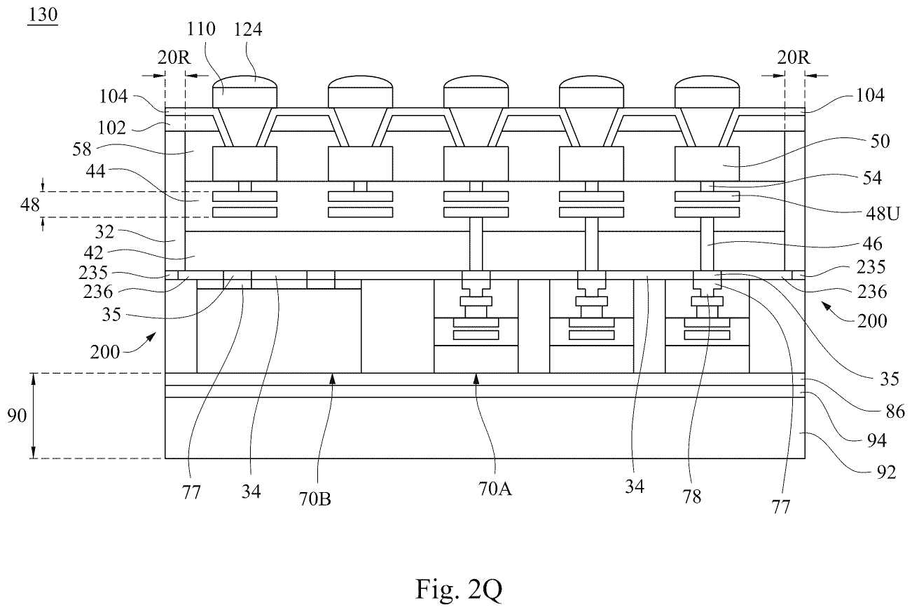

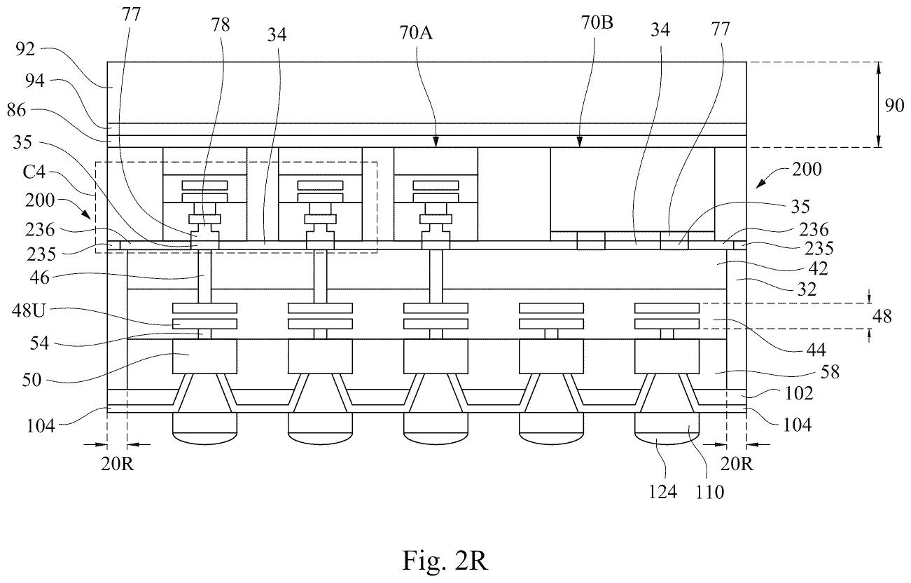

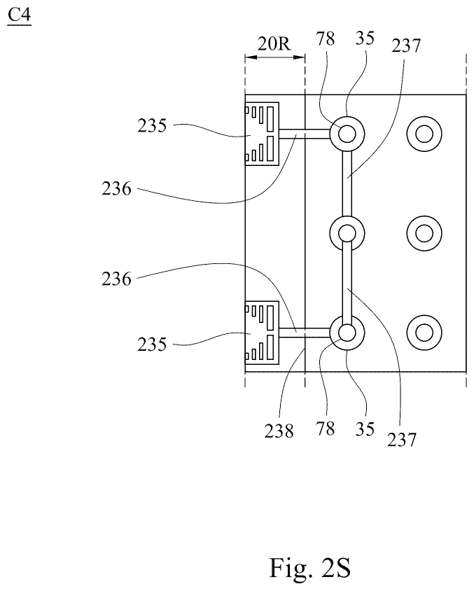

Reference is made to FIGS. 2A-2S. FIGS. 2A-2J and 2L-2Q illustrate cross-sectional views of intermediate stages in the formation of a device package 130 including at least a portion of a monitoring circuit 200 in accordance with some embodiments of the present disclosure. It is understood that additional operations can be provided before, during, and after the processes shown by FIGS. 2A-2S, and some of the operations described below can be replaced or eliminated, for additional embodiments of the method. The order of the operations/processes may be interchangeable. FIG. 2F illustrates a local enlarged top view of a region C2 in FIG. 2E. FIG. 2K illustrates a local enlarged cross-sectional view of a region C3 in FIG. 2J. FIG. 2R illustrates a cross-sectional view of the device package 130 including a monitoring circuit in accordance with some embodiments of the present disclosure. FIG. 2S illustrates a local enlarged top view of a region C4 in FIG. 2R.

Reference is made to FIG. 2A. Package components 40 can be formed or provided, for example, in a wafer (not separately illustrated). In some embodiments, the package components 40 can be individual device dies (e.g., integrated circuit dies), packages having one or more device dies packaged therein, System-on-Chip (SoC) dies including a plurality of integrated circuits integrated as a system, or the like. The device die(s) of the package components 40 may be or may comprise logic dies, memory dies, input-output dies, Integrated Passive Devices (IPDs), the like, or combinations thereof. For example, the logic device die(s) of the package components 40 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) of the package components 40 may include Static Random Access Memory (SRAM) dies, Dynamic Random Access Memory (DRAM) dies, or the like. The device die(s) of the package components 40 may include semiconductor substrates and interconnect structures.

In some embodiments, the package component 40 may include a semiconductor substrate 42 (e.g., a silicon substrate), integrated circuit devices (not separately illustrated) at a front-side surface of semiconductor substrate 42, a dielectric layer 44 formed over the semiconductor substrate 42 and the integrated circuit devices, and an interconnect structure 48 formed through the dielectric layer 44. The integrated circuit devices may include active devices (e.g., NMOS and PMOS transistors), passive devices, and the like. In addition, through-substrate vias (TSVs) 46 may extend partially through semiconductor substrate 42, and may further extend partially through the dielectric layer 44. The interconnect structure 48 can include metal lines at different levels and vias electrically connected to the integrated circuit devices. The interconnect structure 48 can include a plurality of levels of the metal lines. In addition, one or more levels of upper metal lines 48U of interconnect structure 48 may be coupled to corresponding ones of TSVs 46, such as through levels of lower metal lines of interconnect structure 48.

Metal pads 50 are disposed over the dielectric layer 44 and electrically connected to the upper metal lines 48U of the interconnect structure 48 by the conductive vias 54. The metal pads 50 will help facilitate external electrical connection to the integrated circuit of the package components 40 during functional use and/or facilitate external electrical connection during, for example, a wafer acceptance testing (e.g., circuit probe testing) of the package components 40. The metal pads 50 may comprise aluminum, an aluminum-copper alloy, or any suitable material. Although not separately illustrated, the metal pads 50 may be coated with a dielectric layer for protection, such as from oxidizing an exposed surface. In some embodiments, the dielectric layer is an anti-reflective coating (ARC) and comprises an oxide or a nitride, such as silicon oxynitride (SiON), or any suitable material.

In some embodiments, the metal pads 50 can be formed by forming a sacrificial material (not shown) over the dielectric layer 44. Openings are formed in the sacrificial material by first applying a photoresist over a top surface of the sacrificial material, which is patterned using a photolithographic mask. The patterned photoresist is then used as an etching mask to etch openings in the sacrificial material and the dielectric layer 44 to expose the conductive vias 54. To form the openings, the sacrificial material and the dielectric layer 44 may be etched by a suitable process such as dry etching (e.g., reactive ion etching (RIE) or neutral beam etching (NBE), etc.), wet etching, or the like. In some embodiments, the sacrificial material itself is the photoresist, and an energy source (e.g., ultraviolet light) is shined through the photomask to change chemical properties (e.g., solubility) of regions of the sacrificial material impinged by the energy. To form the openings, those regions of the sacrificial material may be etched by a suitable process such as an isotropic wet etch process. The openings within the sacrificial material and the dielectric layer 44 are filled with a conductive material. In an embodiment, the conductive material may comprise a seed layer and a plate metal (not separately illustrated). The seed layer may be blanket deposited over the exposed top surfaces of the conductive vias 54 and dielectric layer 56, and may comprise, for example, a copper layer. The seed layer may be deposited using processes such as sputtering, evaporation, or plasma-enhanced chemical vapor deposition (PECVD), or the like, depending upon the desired materials. The plate metal may be plated from the seed layer through a plating process such as electrical or electro-less plating. The plate metal may comprise aluminum, an aluminum-copper alloy, or the like. A removal process, such as a chemical mechanical polish (CMP) or a grinding process, may be performed to remove the photoresist, the sacrificial material, and portions of the conductive material outside of the openings through dielectric layer 56. The remaining portions of the conductive material (e.g., the seed layer and the plate metal) in the openings through dielectric layer 56 form metal pads 50. Some of the metal pads 50 may be connected to the TSVs 46 by the interconnect structure 48. Some of the metal pads 50 may be connected to the integrated circuit devices at the surface of the semiconductor substrate 42 by the interconnect structure 48.

In some embodiments, a first wafer acceptance testing (WAT) process (e.g., circuit probe testing) may be performed on package components 40 to ascertain whether the package components 40 are known good dies (KGDs). The package components 40 may be tested using one or more probes. The probes are physically and electrically coupled to certain ones of the metal pads 50 by, e.g., reflowable test connectors. Only wafers with the package components 40 which are KGDs undergo subsequent processing and packaging (e.g., SoIC processing/packaging), and wafers with the package components 40 which fail the circuit probe testing are not subsequently processed and packaged. The testing may include providing power and ground voltages to the metal pads 50 in order to test the functionality of the various package components 40 (e.g., the integrated circuit devices and the interconnect structure 48 within). In some embodiments, the circuit probe testing may include testing for known open or short circuits that may be expected based on the integrated circuits within the package components 40. In some embodiments, after testing is complete, the probes are removed and any excess reflowable material on the metal pads 50 may be removed by, e.g., an etching process, a chemical-mechanical polish (CMP), a grinding process, or the like.

Following the first WAT process, a dielectric bond layer 58 may be formed over the metal pads 50 of the package component 40. The dielectric bond layer 58 may be a single homogenous layer or a composite of two or more layers comprising, for example, an oxide and/or a nitride, such as silicon oxide (SiO, such as SiOₓ, wherein x is 2 or less), silicon oxynitride (SiON), silicon nitride (SiN), the like, or any suitable material(s). The dielectric bond layer 58 may be formed using spin coating, Flowable Chemical Vapor Deposition (FCVD), or the like. In some embodiments, after forming the dielectric bond layer 58, individual package components 40 are singulated from the wafer, using any suitable singulation process, in order for the KGDs of the package components 40 to undergo subsequent processing and packaging as discussed below. The singulation process may include mechanical sawing, laser dicing, plasma dicing, combinations thereof, or the like.

Reference is made to FIG. 2B. One or more of singulated package components 40 can be bonded to a carrier 20 through a direct bonding process, such as fusion bonding. After attachment to the carrier 20, the combination of one or more of package components 40 may be referred to herein as a partial semiconductor package. The partial semiconductor package will undergo subsequent processing (e.g., SoIC packaging), during which the one or more of the package component 40 will experience similar conditions as one another. Although two package components 40 are illustrated in any particular region, there may be any number of package components 40 (e.g., KGDs) bonded in a particular region of the carrier 20. In addition, the regions of the carrier 20 may have varying numbers of each of package components 40. The package components 40 may be discrete package components physically separate from each other, and the bonding processes are die-to-wafer bonding.

The carrier 20 may be a substrate and includes a base carrier 22, one or more dielectric bond layers 24. In some embodiments, base carrier 22 may be a wafer and may be a similar material as the semiconductor substrate 42 in the package component 40, so that in this and subsequent processing steps, warpage caused by mismatch of Coefficients of Thermal Expansion (CTE) is reduced. For example, the base carrier 22 may be formed of or comprise silicon, while other materials such as laminate, ceramic, glass, silicate glass, or the like, may also be used. In some embodiments, the entire base carrier 22 can be formed of a homogeneous material, with no other material different from the homogeneous material therein. In some embodiments, the entire base carrier 22 may be formed of silicon (doped or undoped), and without a metal region, dielectric region, etc., therein.

Before attaching the package components 40 to the carrier 20, the dielectric bond layers 24 may be deposited on the base carrier 22. The dielectric bond layers 24 may include oxide-based materials (e.g., silicon oxide based) such as silicon oxide (SiO, such as SiOₓ, wherein x is 2 or less), phospho-silicate glass (PSG), borosilicate glass (BSG), boron-doped phospho silicate glass (BPSG), fluorine-doped silicate glass (FSG), or the like; nitride-based materials such as silicon nitride (SiN) or the like; oxynitride based materials such as silicon oxynitride (SiON) or the like; or other materials such as silicon oxycarbide (SiOC), silicon carbonitride (SiCN), or the like. The dielectric bond layers 24 may be formed using spin-coating, FCVD, Plasma Enhanced Chemical Vapor Deposition (PECVD), Low Pressure Chemical Vapor Deposition (LPCVD), Atomic Layer Deposition (ALD), the like, or combinations thereof. For example, in some embodiments, the dielectric bond layers 24 may include a lowermost layer (e.g., proximal to the base carrier 22) comprising an oxide, one or more middle layers comprising a nitride and/or an oxynitride, and an uppermost layer (e.g., distal from the base carrier 22) comprising an oxynitride (e.g., with a lower nitrogen-to-oxygen ratio as compared with the middle layers). Although not separately illustrated, alignment marks may be formed in the dielectric bonding layers 24 (e.g., the uppermost layer) using any suitable method.

In some embodiments, the bonding of the package components 40 to the carrier 20 may include pre-treating the dielectric bond layers 24 and 58 with a process gas comprising oxygen (O₂) and/or nitrogen (N₂), performing a pre-bonding process to bond the dielectric bond layers 24 and 58 together, and performing an annealing process following the pre-bonding process to strengthen the bond. In some embodiments, during the pre-bonding process, the package components 40 are put into contact with the carrier 20, with a pressing force applied to press the package components 40 against the carrier 20. The pre-bonding may be performed at room temperature (in a range from 20° C. to 25° C.), although a higher temperature may also be used. After the pre-bonding, an annealing process is performed. Chemical bonds, such as Si—O—Si bonds, may be formed between the dielectric bond layers 24 and 58, so that the dielectric bond layers 24 and 58 are bonded to each other with high bonding strength. In some embodiments, the annealing process is performed at a temperature in a range from 200° C. to 350° C. The annealing duration may be in a range from 30 minutes to 60 minutes.

Scribe line regions 20R are non-functional areas that can provide space for a singulation tool to cut without damaging the device areas, such that individual device packages 130 (see FIG. 2Q) can be from adjacent device packages 130 (see FIG. 2P). The scribe line regions 20R provide additional context for the locations of the chip probe pads 235 (see FIG. 2E) and the package components 40. In some embodiments, more than one of the package components 40 may be grouped closely and bounded by scribe line regions 20R in order to be subsequently singulated into an individual semiconductor package comprising more than one of the package components 40.

Reference is made to FIG. 2C. After attaching the package components 40 to the carrier 20, a gap-filling material 32 is formed over the package components 40 and the carrier 20 to encapsulate the package components 40. The gap-filling material 32 may include a liner layer and a bulk layer (not separately illustrated). For example, the liner layer may be a conformal layer extending along the top surfaces and the sidewalls of the package components 40 and along top surfaces of the dielectric bond layer 24. The liner layer may also be referred to as a seal-ring and, in some embodiments, is used as an etch stop layer in subsequent steps. The liner layer may be formed of a dielectric material that has good adhesion to the sidewalls of package components 40, such as an extra low-k (ELK) material, including a nitride such as silicon nitride and/or an oxide such as silicon oxide. The deposition of the liner layer may include a conformal deposition process such as ALD, CVD, or any suitable process. The bulk layer of the gap-filling material 32 may be formed of a molding compound, an epoxy, a resin, and/or the like. For example, the bulk layer may comprise a nitride such as silicon nitride and/or an oxide such as silicon oxide and may be deposited using spin coating, FCVD, PECVD, LPCVD, ALD, or any suitable process. By way of example and not limitation, the gap-filling material 32 may include SiOx, SiN, SiON, polyimid (PI), organic, dielectric, or a combination thereof.

Reference is made to FIG. 2D. A planarization process such as a CMP process and/or a mechanical grinding process is then performed to remove portions of the gap-filling material 32 (e.g., the liner layer and the bulk layer) from over the back-side surfaces (the illustrated top surfaces) of the package components 40. In some embodiments, the planarization process is continued in order to thin portions of the semiconductor substrate 42 until the TSVs 46 are exposed. After the planarization process, a back-side surface of each semiconductor substrate 42 may be coplanar (within process variations) with a top surface of the gap-filling material 32.

Reference is made to FIGS. 2E and 2F. A dielectric bond layer 34 and bond pads 35 are formed over the back-side surface of the package component 40 (e.g., the upper surface of the semiconductor substrate 42 as illustrated), circuit probe pads 235 are formed over the gap-filling material 32 in the scribe line regions 20R, and metal lines 236 are formed to extend from the circuit probe pads 235 to the bond pads 35 across an interface between the package components 40 and the gap-filling material 32. In some embodiments, additional metal lines 237 (see FIG. 2F) can be formed over the back-side surface of the package component 40 and connect adjacent two of the bond pads 35.

The bond pads 35 can be formed over and electrically connected with the TSVs 46. The bond pads 35 can provide a direct electrical connection between the TSVs 46 or other electrical pathways within the package components 40. This connection is for creating the electrical pathways needed for the integrated circuit to function properly. The bond pads 35 can act as accessible points for testing the electrical functionality of the package components 40 during the manufacturing process. That is, the bond pads 35 can be used to probe the electrical characteristics of the circuits, ensuring that the components are functioning correctly before they are fully integrated. In addition, the bond pads 35 can contribute to the physical bonding between different package components (e.g., package components 70A and 70B as shown in FIG. 2G). In some embodiments, the bond pads 35 can aid in heat dissipation, as they can be part of the thermal management system within the package (e.g., package component 70B), helping to transfer heat away from critical components.

The circuit probe pad 235 can physically connect with probes 240 (see FIG. 2H), allowing for precise alignment and stable contact between the probes 240 and the semiconductor device (e.g., package components 70A and 70B as shown in FIG. 2G). Once physically coupled, the probes 240, through the circuit probe pads 235, create an electrical connection that enables the testing equipment to send and receive signals from the semiconductor device to perform a circuit probe (CP) test. The circuit probe test is to verify the functionality and integrity of the electrical circuits within the semiconductor device. By interfacing with the circuit probe pad 235, the circuit probe test can evaluate various electrical properties, such as current flow, resistance, and voltage levels across different parts of the circuitry. In some embodiments, the circuit probe test can determine the bonding quality between the package components 40 and the components 70A and 70B (see FIG. 2H). For example, a good bonding performance can ensures that there is a reliable electrical connection with no discontinuities or failures, which is for the semiconductor device's performance and longevity.

In some embodiments, poor bonding between package components, such as between package component 40 and components 70A and 70B as shown in FIG. 2G can occur. If the surfaces of the package components 40 or the components 70A and 70B to be bonded are contaminated with particles, oils, or other residues, the bond may not form correctly, leading to weak adhesion and poor electrical contact. In some embodiments, incompatibilities of the materials of the bonding surfaces can result from differences in thermal expansion coefficients, metal reactivity, or other material properties, resulting in poor bonding. In some embodiments, deviations of the bonding process parameters such as temperature, pressure can lead to inadequate bonding, such as cold solder joints in the case of soldering or incomplete curing for adhesives, resulting in poor bonding.

In some embodiments, the dielectric bond layer 34 can be first deposited over the package components 40 and the gap-filling material 32 using any suitable method such as ALD, CVD, or the like. The dielectric bond layer 34 may then be patterned to form openings, which are filled with a conductive material to form the bond pads 35 and the circuit probe pads 235, similarly as described above in connection with the metal pads 50. In some embodiments, the bond pads 35, the circuit probe pad 235, the metal line 236, and/or the metal line 237 may include Cu, Al, AlCu, Ni, SnCu, or a combination thereof. In some embodiments, the simultaneous formation of the circuit probe pad 235, the metal line 236, and/or the metal line 237 can eliminate the need for separate processing phases for each elements, streamlining the overall manufacturing timeline. Since the circuit probe pad 235, the metal line 236, and/or the metal line 237 can be created together, the process requires fewer materials and reduces the labor and equipment usage needed for multiple steps, such that the total cost of manufacturing can be reduced. When the circuit probe pad 235, the metal line 236, and/or the metal line 237 are fabricated at the same time, they can be made from the same material, ensuring consistency in the thermal and electrical properties across the different parts of the circuit.

Reference is made to FIG. 2G. The package components 70A and 70B are attached to package components 40 to form device packages 130. The package components 70A and 70B may include active package components 70A and dummy package components 70B. The active package components 70A may include integrated circuits. The dummy package components 70B may be included for purposes of structural integrity and/or heat dissipation during fabrication and/or during functional use of the completed semiconductor package. For example, the active package components 70A may be attached through a hybrid bonding process, and the dummy package components 70B may be attached through a direct bonding process, such as fusion bonding.

In some embodiments, the active package components 70A may be the same as, similar to, or different from the package components 40. For example, the active package components 70A may be individual device dies (e.g., integrated circuit dies), packages having one or more device dies packaged therein, System-on-Chip (SoC) dies including a plurality of integrated circuits (or device dies) integrated as a system, or the like. The device die(s) of the active package components 70A may be or may comprise logic dies, memory dies, input-output dies, Integrated Passive Devices (IPDs), the like, or combinations thereof. For example, the logic device die(s) of the active package components 70A may be Central Processing Unit (CPU) dies, Graphic Processing Unit (GPU) dies, mobile application dies, Micro Control Unit (MCU) dies, BaseBand (BB) dies, Application processor (AP) dies, or the like. The memory die(s) of the active package components 70A may include Static Random Access Memory (SRAM) dies, Dynamic Random Access Memory (DRAM) dies, or the like. The device die(s) of active package components 70A may include semiconductor substrates and interconnect structures. In some embodiments, the package components 40 are SoC dies, and the active package components 70A are memory dies, such as SRAM dies.

In some embodiments, the active package components 70A may include features similar to those described above in the package components 40. For example, the active package components 70A may include a semiconductor substrate, integrated circuit devices (not separately illustrated), and a plurality of dielectric layers formed over the semiconductor substrate and the integrated circuit devices. The integrated circuit devices may include active devices, passive devices, and the like.

In some embodiments, the dummy package components 70B do not include functional integrated circuits and/or are electrically disconnected from the package components 40 and the package components 70A. As discussed above, the active package components 70A may provide structural support for the semiconductor package as well as heat dissipation from the package components 40 and/or the active package components 70A during functional use of the semiconductor package.

The bonding of the active package components 70A to the package components 40 may be achieved through hybrid bonding, in which both of metal-to-metal direct bonding and dielectric-to-dielectric bonding (such as Si—O—Si bonding between surface dielectric bond layers) are formed. Furthermore, there may be a single or a plurality of the active package components 70A bonded to the same package component 40. The plurality of the active package components 70A bonded to the same package component 40 may be identical to, or different from, each other.

In some embodiments, a dielectric bond layer of the package component 70A/70B can bonded to a dielectric bond layer of the package component 40 through dielectric-to-dielectric bonding, without using any adhesive material (e.g., die attach film). Similarly, the bond pads 77 are bonded to the bond pads 35 through metal-to-metal bonding, without using any eutectic material (e.g., solder). The bonding may include a pre-bonding and an annealing. During the pre-bonding, a small pressing force is applied to press the active package components 70A against the package components 40. The pre-bonding is performed at a low temperature, such as room temperature, such as a temperature in the range from 20° C. to 25° C., and after the pre-bonding, the dielectric bond layers of the package component 70A/70B and the package component 40 can be bonded to each other. The bonding strength is then improved in a subsequent annealing step, in which dielectric bond layers of the package component 70A/70B and the package component 40 are annealed at a high temperature, such as a temperature in the range from 200° C. to 350° C. After the annealing, bonds, such as fusion bonds, are formed bonding dielectric bond layers. For example, the bonds can be covalent bonds between the materials of dielectric bond layers. The bond pads 77 and the bond pads 35 can be connected to each other with a one-to-one correspondence. The bond pads 77 and the bond pads 35 may be in physical contact after the pre-bonding, or may expand to be brought into physical contact during the annealing. Further, during the annealing, the material of the bond pads 77 (e.g., copper) and the material of the bond pads 35 (e.g., copper) intermingles, so that metal-to-metal bonds are also formed. Hence, the resulting bonds between the active package components 70A and the package components 40 are hybrid bonds that include both dielectric-to-dielectric bonds and metal-to-metal bonds.

The bonding of the dummy package components 70B to the package components 40 may be performed before, after, or at various points during attachment of the active package components 70A. The bonding of the dummy package components 70B is achieved through direct bonding, in which dielectric-to-dielectric bonding (such as Si—O—Si bonding between surface dielectric bond layer) is formed. Furthermore, there may be a single or a plurality of the dummy package components 70B bonded to the same package component 40. The plurality of the dummy package components 70B bonded to the same package component 40 may be identical to, or different from, each other.

After the attachment of the package components 70A and 70B, the monitoring circuit 200 can be formed as a diagnostic feature integrated into the semiconductor package to assess the quality of the bonding between the package components 40 and the package components 70A and 70B. The monitoring circuit 200 can include the circuit probe pads 235, the bond pads 35, and the metal lines 236 and 237. The circuit probe pads 235 can interface with external testing equipment (e.g., probes 240 as shown in FIG. 2H). During the circuit probe test, probes 240 make contact with the circuit probe pads 235 to test the circuit's electrical characteristics. The bond pads 35 can be the points of electrical and physical connection to the TSVs 46 or other internal connectors within the package components 70A and 70B (e.g., bond pads 77) for creating a continuous electrical path across the different layers of the package. The metal lines 236 can serve as the conductive pathways that connect the circuit probe pads 235 to the bond pads 35 for the functionality of the circuit probe test, as they enable the transmission of electrical signals during testing. The metal lines 237 (see FIG. 2F) can be part of daisy chain structures (see FIGS. 1C-1E) within the package components 70A and 70B. Daisy chaining is a method where components are connected in series, one after another, which allows for the entire chain to be tested for continuity. Breaks or defects in the daisy chain indicate potential issues with bonding quality between the package components 40 and the package components 70A and 70B.

By integrating these components (e.g., circuit probe pads 235, bond pads 35, and metal lines 236 and 237), the monitoring circuit 200 can effectively determine the integrity of the bond between different package components. When a circuit probe test is conducted, the circuit probe test can measure electrical properties such as resistance and continuity. Deviations from expected values can indicate poor bonding, prompting further inspection or rework before additional manufacturing processes continue. This circuit probe test can ensure the reliability of the semiconductor package before it reaches later stages of production.

In some embodiments, the metal lines 237 may be integrated into either package component 70A or 70B. The metal lines 237 can be part of the circuitry that establishes the necessary electrical connections for the device's functionality. In some embodiments, the metal lines 237 can be implemented not as part of the electrical signal path but as separate entities. The metal lines 237 can be distinct from the circuitry, often dedicated to testing or monitoring functions of the bonding performance. For example, the metal lines 237 may be added for the sole purpose of assessing the bond quality between the package components (e.g., package components 40 and package components 70A and 70B). The metal lines 237 can be placed to facilitate the detection of bonding integrity without interfering with the main electrical pathways. The metal lines 237 could be positioned on the back-side surface of the package component 40, spanning between two adjacent bond pads 35, creating a testable loop or circuit that can be accessed and measured during quality control tests. During the circuit probe test, the metal lines 237 can allow for the application of signals or the measurement of electrical properties (e.g., resistance or capacitance) across the bonding interface. Changes in these properties would indicate the state of the bonding between the package components 40 and the package components 70A/70B, revealing whether the bonding is within acceptable parameters. By including such dedicated metal lines for bond quality assessment, manufacturers can ensure that any potential bonding issues are identified early in the circuit probe test, thereby reducing the risk of failure in the final assembled package.

Reference is made to FIG. 2H. The circuit probe test can be performed to evaluate the quality of electrical connections between the package components 40 and the package components 70A/70B. In FIG. 2H, the circuit probe test can be used to determine the quality of the bonding between the package components 40 and the components 70A and 70B. During the circuit probe test, the probes 240 can be brought into contact with the circuit probe pads 235. The circuit probe pads 235 can be electrically connected to the structures that include the bonds between the package components 40 and the components 70A and 70B.

Specifically, the circuit probe test can measure the resistance of the electrical paths between the package components 40 and the components 70A and 70B. Under good bonding conditions, the resistance should be low and within specified tolerances, indicating that the bond pads are properly connected and that there is a solid intermetallic connection. If the bonding is poor (e.g., no contact), such as due to incomplete soldering, contamination, or voids in the bond, the resistance will be higher than expected. This is because poor bonding can result in a reduced contact area or introduce defects that impede current flow. The test equipment 245 connected to the probes 240 may compare the measured resistance values against known good profiles (e.g., from a database of acceptable resistance measurements for well-bonded connections) to determine if the bond quality is within acceptable limits. In some embodiments, the circuit probe test may involve dynamic testing where resistance is measured under varying electrical loads or temperatures to assess the stability of the bond under operating conditions. A deviation from the expected resistance value would suggest a problem with the bond, triggering a need for rework or scrapping of the semiconductor structure. Therefore, by applying circuit probe tests across the semiconductor structures and interpreting the resistance data, the quality of the bonding across the entire wafer, identifying any areas of concern that need to be addressed.

Before the under-bump metallurgies (UBMs) 110 (see FIG. 2O) and conductive connectors 124 (see FIG. 2P) are formed, the monitoring circuit 200 can be applied to be used in quality control during the semiconductor packaging process. The circuit probe pad 235 can be accessible for testing before committing to further manufacturing steps like the application of under-bump metallurgies 110 and the conductive connectors 124, which are more advanced stages of the assembly process. By testing at this stage, manufacturers can identify any defective bonding between the package components 40 and the components 70A and 70B early on. Detecting such defects before more layers and complexity are added to the package components 40 and the components 70A and 70B can avoid the additional costs that would be incurred if the defect were found after further processing. The circuit probe test involving the monitoring circuit 200 can help in verifying that the bonding quality meets the necessary standards. If the test indicates good bonding, manufacturing proceeds to the next stages. If the bonding is found to be poor, corrective measures can be taken immediately. In cases where poor bonding is detected, the manufacturing process can be paused, and remedial actions can be taken. These remedial actions might include reflowing the solder, adding or removing materials, or even discarding the affected components before additional time and resources are invested. By incorporating such early testing protocols, the semiconductor manufacturing process can become more reliable and cost-effective, as defects are caught and addressed at the earliest possible stage.

Reference is made to FIG. 2I. After attaching package components 70A and 7B to the package components 40, a gap-filling material 82 can be formed over and between the package components 70 to encapsulate the package components 70. The gap-filling material 82 may be formed similarly as described above in connection with the gap-filling material 32. For example, the gap-filling material 82 may include a liner layer and a bulk layer (not separately illustrated). The liner layer may be a conformal layer extending along the top surfaces and the sidewalls of the package components 70 as well as along exposed top surfaces of dielectric bond layer 34. The liner layer may also be referred to as a seal-ring and be formed of a dielectric material that has good adhesion to the sidewalls of the package components 70A and 70B, such as an extra low-k (ELK) material, including a nitride such as silicon nitride and/or an oxide such as silicon oxide. The deposition of the liner layer may include a conformal deposition process such as ALD, CVD, or any suitable process. The bulk layer of the gap-filling material 82 may be formed of a molding compound, an epoxy, a resin, and/or the like. For example, the bulk layer may comprise a nitride such as silicon nitride and/or an oxide such as silicon oxide. For example, the liner layer and the gap-filling material 82 may be formed similarly as described above in connection with the gap-filling material 32.

Subsequently, a planarization process such as a CMP process and/or a mechanical grinding process is then performed to remove portions of the gap-filling material 82 (e.g., the liner layer and the bulk layer) from over the illustrated top surfaces of the active package components 70A and/or the dummy package components 70B. For example, a thinning process may be utilized, such as a CMP process, a grinding process, an etch back process, the like, or combinations thereof.

Reference is made to FIGS. 2J and 2K. A carrier 90 can be bonded to package the package components 70A and 70B through a direct bonding process, such as fusion bonding. The carrier 90 may be a substrate and includes a base carrier 92 and one or more dielectric bond layers 94. The base carrier 92 may be a wafer, and may be formed of a same material as, for example, the base carrier 22 in the carrier 20, so that in the subsequent packaging process, the warpage caused by mismatch of Coefficients of Thermal Expansion (CTE) is reduced. In some embodiments, the base carrier 92 may be formed of or comprise silicon, while other materials such as laminate, ceramic, glass, silicate glass, or the like, may also be used. In some embodiments, the entire base carrier 92 is formed of a homogeneous material, with no other material different from the homogeneous material therein. For example, the entire base carrier 92 may be formed of silicon (doped or undoped), and there is no metal region, dielectric region, etc., therein.

Before attaching the carrier 90 to the package components 70A and 7B, one or more dielectric bond layers 94 are deposited on base carrier 92 and one or more dielectric bond layers 86 are deposited over package components 70. The dielectric bond layers 86 and 94 may be formed similarly as described above in connection with any of the dielectric bond layers 24/34/58. In some embodiments, the bonding of the carrier 90 to the package components 70A and 70B can include pre-treating dielectric the bond layers 86 and 94 in a process gas comprising oxygen (O₂) and/or nitrogen (N₂), performing a pre-bonding process to the bond dielectric bond layers 86 and 94 together, and performing an annealing process following the pre-bonding process to strengthen the bond. In some embodiments, during the pre-bonding process, the carrier 90 is put into contact with the dielectric bond layers 86, with a pressing force applied to press the carrier 90 against the package components 70A and 70B. The pre-bonding may be performed at room temperature (in a range from 20° C. to 25° C.), although a higher temperature may also be used. After the pre-bonding, an annealing process is performed. Chemical bonds, such as Si—O—Si bonds, may be formed between the dielectric bond layers 86 and 94, so that dielectric bond layers 86 and 94 are bonded to each other with high bonding strength. In some embodiments, the annealing process is performed at a temperature in a range from 200° C. to 350° C. The annealing duration may be in a range from 30 minutes to 60 minutes.

Reference is made to FIG. 2L. The structure shown in FIG. 2L may be flipped, and the carrier 20 is removed to expose the dielectric bond layer 58 of the package components 40. The carrier 20 may be removed using any suitable method, such as a planarization process. The planarization process may continue until surfaces of dielectric bond layer 58 can be coplanar (within process variations) with a surface of the gap-filling material 32. The planarization process may be a CMP process, a grinding process, the like, or a combination thereof.

Reference is made to FIG. 2M. A passivation layer 102 may be formed over the package components 40, openings 106/107 are formed in the passivation layer 102. The openings 106 can be formed through the passivation layer 102 to expose the metal pads 50. Specifically, the passivation layer 102 may be a single layer or a plurality of layers and be conformally deposited as an oxide such as silicon oxide, a nitride such as silicon nitride, silicon oxynitride, the like, or combinations thereof. For example, a silicon oxide lower layer (not separately illustrated) may be first deposited over the dielectric bond layer 58. A silicon nitride upper layer (also not separately illustrated) may then be deposited over the silicon oxide lower layer. The single or plurality of layers comprising passivation layer 102 may be deposited using any suitable methods, such as CVD, ALD, combinations thereof, or any suitable methods.

Subsequently, the passivation layer 102 may then be patterned to form openings 106 through passivation layer 102. Openings 106 may then be extended through the dielectric bond layer 58. For example, a photoresist may be applied over a top surface of the passivation layer 102 and patterned. The patterned photoresist is then used as an etching mask to etch portions of the passivation layer 102 to expose the dielectric bond layer 58. In some embodiments, the etching process stops at the dielectric bond layer 58 so that the metal pads 50 remain covered. In some embodiments, the etching process continues through the dielectric bond layer 58 to expose metal pads 50. The passivation layer 102 may be etched by a suitable process such as dry etching (e.g., reactive ion etching (RIE), neutral beam etching (NBE), etc.), wet etching, or the like. In some embodiments, the etchants may be selected such that the passivation layer 102 and/or the dielectric bond layer 58 have high etch selectivities as compared with one another or with a dielectric coating layer (not separately illustrated) protecting the metal pads 50. As such, the dielectric bond layer 58 and/or the dielectric coating layer therefore serves as an etch stop layer during the etching process.

Reference is made to FIG. 2N. A dielectric layer 104 may be formed over the passivation layer 102 and patterned. Specifically, the dielectric layer 104 may be formed of a polymer material such as polyimide, silicon oxide (SiO, such as SiOₓ, wherein x is 2 or less), the like, or any suitable material. Dielectric layer 104 may be conformally formed using, for example, spin coating, FCVD, PECVD, LPCVD, ALD, the like, or combinations thereof. As illustrated, the dielectric layer 104 is formed over the top surface and along exposed sidewalls of passivation layer 102 as well as along exposed sidewalls of the dielectric bond layer 58 within the openings 106. As such, the dielectric layer 104 partially fills and extends entirely across the openings 106. Subsequently, the dielectric layer 104 may then be patterned to re-form the openings 106. For example, a photoresist may be applied over a top surface of the dielectric layer 104 and patterned. The patterned photoresist is then used as an etching mask to etch the dielectric layer 104 in order to re-form the openings 107 and expose the metal pads 50. The dielectric layer 104 may be etched by a suitable process such as dry etching (e.g., RIE or NBE, etc.), wet etching, or the like.

Reference is made to FIG. 2O. The under-bump metallurgies (UBMs) 110 are formed over the dielectric layer 104 and in the openings 106 to be electrically connected to the metal pads 50. As an example to form the under-bump metallurgies 110, a seed layer (not separately illustrated) is formed over the exposed surfaces of the metal pads 50 and the dielectric layer 104. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the under-bump metallurgies 110. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the under-bump metallurgies 110.

Reference is made to FIG. 2P. Conductive connectors 124 can be formed on under-bump metallurgies 110, respectively. The conductive connectors 124 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 124 may include a conductive material such as solder, copper, aluminum, gold, nickel, silver, palladium, tin, the like, or a combination thereof. In some embodiments, conductive connectors 124 are formed by initially forming a layer of solder through evaporation, electroplating, printing, solder transfer, ball placement, or the like. Once a layer of solder has been formed on the structure, a reflow may be performed in order to shape the material into desired bump shapes. In some embodiments, the conductive connectors 124 can include metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Reference is made to FIGS. 2Q-2S. As shown in FIG. 2Q, the individual device packages 130 can be singulated from adjacent device packages 130. A singulation process is a step in separating the individual device packages 130 from each other, ensuring that each device package 130 can be independently handled and mounted onto a circuit board or integrated into a larger system. The singulation process can be performed along scribe line regions 20R (see FIG. 2Q). The scribe line regions 20R can be pre-designed pathways that outline the periphery of each individual device package 130, which in turn facilitates the singulation process without interfering with the active regions of the semiconductor devices. By way of example and not limitation, the singulation process may include a sawing method, a laser cutting method, other suitable methods, or combination thereof. In some embodiments, the sawing method may involve a diamond-tipped blade or a blade coated with another hard material that can cut through the scribe line regions 20R. The saw blade is aligned with the scribe line regions 20R and moves through the material to mechanically separate each device package 130. Alternatively, a laser cutting process may involve the use of a high-powered laser to ablate or vaporize the material along the scribe line regions 20R. The laser can be precisely controlled to follow the scribe line regions 20R, ensuring that the cuts are made at the correct location and depth to separate the device packages 130 without damaging them. After the singulation process, each device package 130 can be individually tested and prepared for assembly, such as being mounted onto a printed circuit board (PCB).

As shown in FIGS. 2R and 2S, the structure shown in FIG. 2R is flipped from the structure shown in FIG. 2Q, and FIG. 2S illustrates the local enlarged top view of the region C4 in FIG. 2R. The monitoring circuit 200 can be integrated into the wafer layout such that it straddles the scribe line regions 20R, which are the designated areas for cutting or singulation between individual device packages 130. When the scribe line region 20R is cut, the monitoring circuit 200 that overlaps the scribe line region 20R is also be cut, allowing for a portion of the monitoring circuit 200 to become a portion of the singulated device package 130. After the singulation process, a remainder of the monitoring circuit 200 (e.g., circuit probe pad 235 and metal line 236 that are connected to it) may remain attached to the device package 130 as shown in FIG. 2S. The inclusion of a portion of the monitoring circuit 200 on the device package 130 can indicate a design that incorporates testability and monitoring to determine the bonding quality between the package components 40 and the components 70A and 70B in the step as shown in see FIG. 2H.

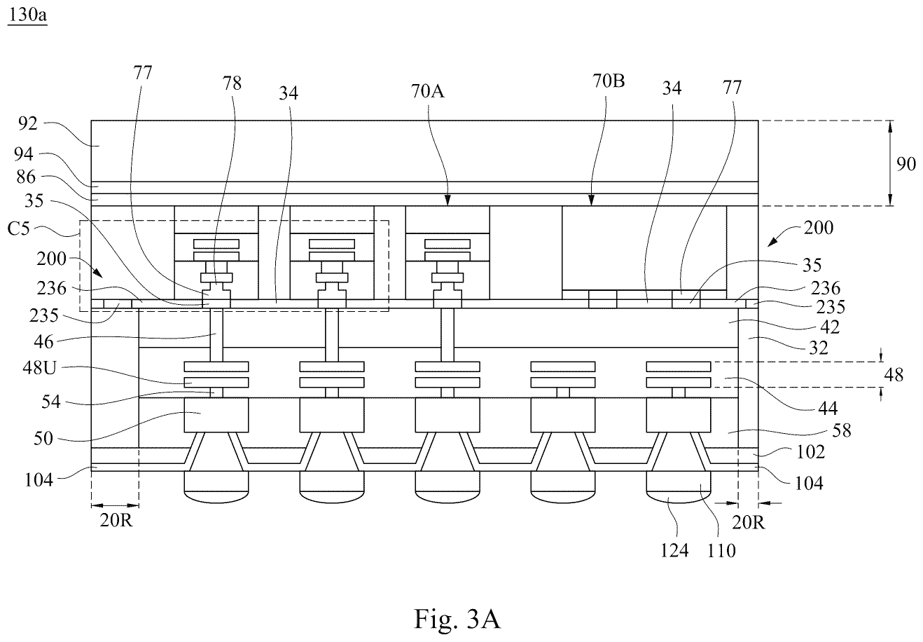

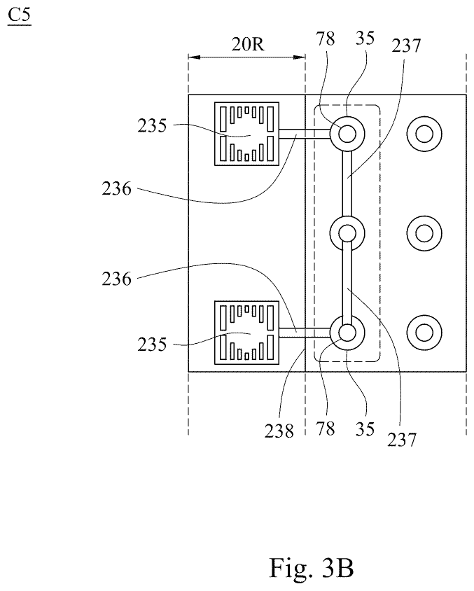

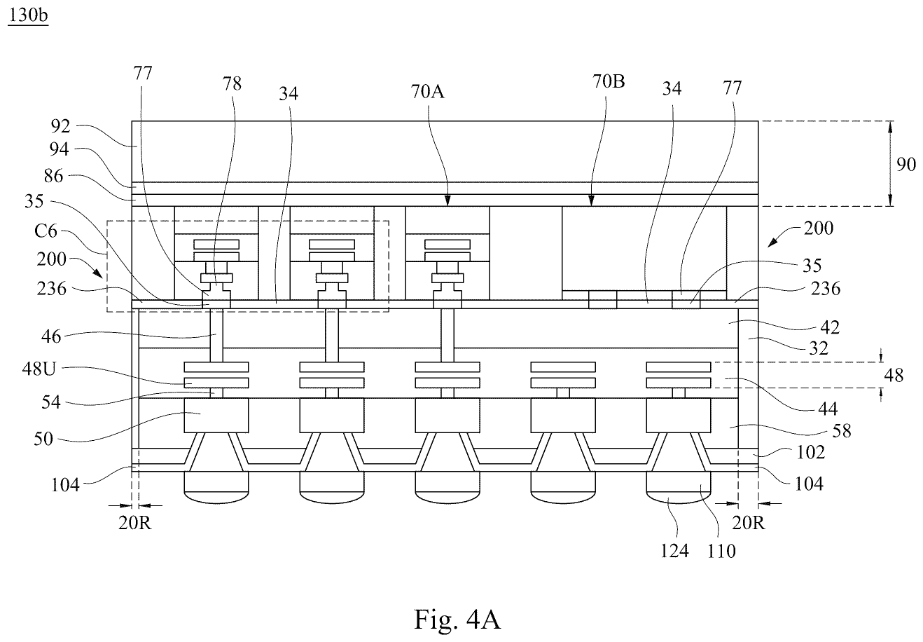

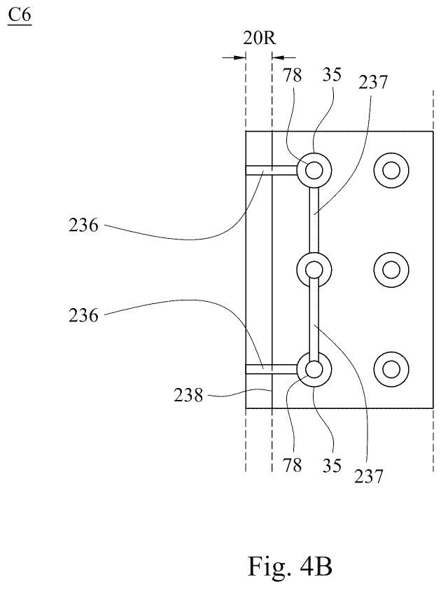

Reference is made to FIGS. 3A-4B. FIGS. 3A and 4A illustrate cross-sectional views of device packages 130a and 130b including at least portions of the monitoring circuits 200 corresponding to FIG. 2R in accordance with some embodiments of the present disclosure. FIGS. 3B and 4B illustrate local enlarged top views of regions C5 and C6 in FIGS. 3A and 3B. While FIGS. 3A-4B show embodiments of device packages 130a and 130b with different cutting positions than in FIG. 2Q. In addition, the present disclosure may repeat reference numerals and/or letters in the various examples. This repetition is for the purpose of simplicity and clarity and does not in itself dictate a relationship between the various embodiments and/or configurations discussed.

Specifically, the position where the singulation process cuts through the scribe line region 20R can affect what portions of the monitoring circuit 200 remain on the singulated device packages 130, 130a, and 130b. In FIGS. 3A and 3B, the cutting position is positioned further from the package component 40 and the package component 70A than the cutting position shown in FIG. 2Q. As a result, the monitoring circuit 200 on the device package 130a can remain intact and uncut, allowing for the entire structure of the monitoring circuit 200 to be present on the device package 130a after the singulation process. Alternatively, in FIGS. 4A and 4B, the cutting position is positioned closer to the package components 40 and the package component 70A than the cutting position shown in FIG. 2Q. This proximity to the package components 40 and the package component 70A means that the cut may sever portions of the monitoring circuit 200. Specifically, the circuit probe pad 235 may be completely separated from the device package 130b during the singulation process, leaving only the metal line 236 on the scribe line region 20R attached to the device package 130b. In some embodiments, an Energy-Dispersive X-ray Spectroscopy (EDX) can be used for characterizing the elemental composition in the semiconductor packaging, for inspecting the device package 130. The EDX can used in analyzing the metallic elements that may be residues from the circuit probe pad 235 and/or the metal line 236 connecting the circuit probe pad 235 to the bond pad 35.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a layout (e.g., monitoring circuit 200 shown in FIGS. 1A and 1B) for hybrid bonding wafer acceptance testing (WAT) design, focusing on the chip boundary and scribe line areas. This layout is for addressing the challenges of hybrid bonding in SoIC fabrication. The layout can facilitate early detection of the performance and integrity of hybrid bonding. Hybrid bonding is a process used to join two semiconductor wafers or die (e.g., package component 40 and package component 70A/70B) using a combination of metal-to-metal and dielectric-to-dielectric bonding, enabling fine-pitch interconnections. Test patterns (e.g., monitoring circuit 200) can be placed at the chip's boundaries and scribe line areas, the regions that are for ensuring the structural and functional integrity of the chip. By focusing on these areas, the design allows for early assessment of the bonding quality during the manufacturing process. This approach can help in identifying any bonding issues before the chip progresses too far in the production line, thereby reducing waste and improving overall yield.

In some embodiments, a method includes bonding a first package component to a substrate; forming a first dielectric material laterally surrounding the first package components; forming a first probe pad over the first dielectric material, a first bond pad on the first package component, and a first metal line connecting the first probe pad to the first bond pad; bonding a second package component to the first package component through the first bond pad. In some embodiments, the method further includes forming a second bond pad on the first package component; forming a second metal line extending from the first bond pad to the second bond pad. In some embodiments, the step of forming the first probe pad, the first bond pad, and the first metal line and the step of forming the second bond pad and the second metal line are performed simultaneously. In some embodiments, the method further includes forming a second probe pad over the first dielectric material, a second bond pad on one of the first package component, and a second metal line connecting the first probe pad to the first bond pad. In some embodiments, the method further comprising: performing a wafer acceptance testing (WAT) process through the first and second probe pads over the first dielectric material. In some embodiments, the method further includes after performing the WAT process, forming a second dielectric material laterally surrounding the second package component. In some embodiments, the method further includes performing a singulation process on the one of the first package component having the second package component thereon along the first dielectric material, allowing for cutting the first probe pad over the first dielectric material. In some embodiments, bonding the second package component to the one of the first package component is performed by a hybrid bonding. In some embodiments, the second package component is a dummy package component. In some embodiments, the second package component is an active package component.

In some embodiments, a method includes bonding a plurality of first package components from front-sides thereof to a carrier, the first package components each comprising a substrate on a back-side thereof and a through-substrate via (TSV) partially extending through the substrate; depositing a dielectric material over the carrier from the back-sides of the first package components; performing a planarization process on the dielectric material and the substrates until the TSVs are exposed, allowing for a remainder of the dielectric material remaining between the first package components; forming a plurality of probe pads over the remainder of the dielectric material, a plurality of bond pads on one of the first package components, the bond pads being electrically coupled to the probe pads; bonding a second package component to the one of the first package components through the bond pads. In some embodiments, the method further includes performing a circuit probe test through the probe pads over the remainder of the dielectric material. In some embodiments, the step of bonding the second package component forms a daisy chain comprising the bond pads and a circuit in the second package component. In some embodiments, the daisy chain further comprises a metal line connecting a first one of the bond pad to a second one of the bond pads. In some embodiments, the second package component comprises a plurality of aluminum pad in the circuit, and the daisy chain further comprises a metal line connecting a first one of the aluminum pads to a second one of the aluminum pads. In some embodiments, the second package component is a charge coupled device die.

In some embodiments, a device package includes a first package component, a second package component, a first dielectric material, and a conductive line. The first package component has a first bond pad. The second package component has a second bond pad. The second package component bonds to the first package component through the first and second bond pads. The first dielectric material laterally surrounds the first package component. The conductive line laterally extends from the first bond pad across an interface between the first package component and the first dielectric material from a cross sectional view. In some embodiments, the device package further includes a metal pad over the first dielectric material. The conductive line connects the first bond pad to the metal pad. In some embodiments, the device package further includes a second dielectric material laterally surrounding the second package component. The metal pad is sandwiched between the first and second dielectric materials. In some embodiments, the conductive line comprises copper, aluminum, aluminum copper, nickel, stannum copper, or combinations thereof. In some embodiments, from a top view, a width of the conductive line is smaller than a width of the first bond pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a first semiconductor die to a first substrate, the first semiconductor die comprising a second substrate and a through-substrate via (TSV) extending at least partially through the second substrate;
forming a first dielectric material laterally surrounding the first semiconductor die;
forming a probe pad over the first dielectric material;
forming a bond pad over the TSV, the bond pad being electrically coupled to the probe pad; and
bonding a second semiconductor die to the first semiconductor die through the bond pad, wherein the probe pad is laterally offset from the second semiconductor die.

2. The method of claim 1, wherein bonding the first semiconductor die to the first substrate is performed by a fusion bonding.

3. The method of claim 1, wherein forming a dielectric material laterally surrounding first the semiconductor die comprises:
depositing the dielectric material over the first semiconductor die; and
planarizing the dielectric material to expose the TSV.

4. The method of claim 1, wherein the probe pad and the bond pad have different top-view profiles.

5. The method of claim 1, further comprising:
performing a circuit probe test, wherein during the circuit probe test, a probe makes contact with the probe pad formed over the first dielectric material.

6. The method of claim 1, further comprising:
forming a second dielectric material over the probe pad and laterally surrounding the second semiconductor die.

7. The method of claim 1, further comprising:
bonding a third substrate to a side of the second semiconductor die opposite the first substrate, wherein the third substrate covers the probe pad formed over the first dielectric material.

8. The method of claim 1, further comprising:
performing a singulation process along an edge of the second semiconductor die to cut through at least a portion of the first dielectric material.

9. The method of claim 8, wherein the singulation process further cuts through at least a portion of the bond pad.

10. The method of claim 8, further comprising:
forming a metal line connecting the probe pad to the bond pad, wherein the singulation process further cuts through at least a portion of the metal line.

11. A method, comprising:
forming a dielectric material laterally surrounding a first semiconductor die;
forming a metal pad over the dielectric material;
forming a first bond pad on the first semiconductor die, the first bond pad being electrically coupled to the metal pad;
bonding a second semiconductor die to the first semiconductor die through the first bond pad; and
after bonding the second semiconductor die, performing a circuit probe test, wherein during the circuit probe test, a probe makes contact with the metal pad formed over the dielectric material.

12. The method of claim 11, wherein the metal pad and the first bond pad are formed on a same side of the first semiconductor die.

13. The method of claim 11, further comprising:
forming a metal line extending from the first bond pad to the metal pad.

14. The method of claim 11, further comprising:
forming a second bond pad on the first semiconductor die; and
forming a metal line on the first semiconductor die, the metal line electrically connecting the second bond pad to the first bond pad.

15. The method of claim 11, wherein bonding of the second semiconductor die to the first semiconductor die is performed by a hybrid bonding process.

16. A device package, comprising:
a first semiconductor die having a first bond pad;
a second semiconductor die having a second bond pad, the second semiconductor die being bonded to the first semiconductor die through the first and second bond pads;
a first dielectric material laterally surrounding the first semiconductor die;
a second dielectric material laterally surrounding the first semiconductor die and disposed over the first dielectric material; and
a first metal feature disposed between the first dielectric material and the second dielectric material, the first metal feature being electrically coupled to the first bond pad and the second bond pad.

17. The device package of claim 16, further comprising:
a first conductive line laterally extending from the first bond pad across an interface between the first semiconductor die and the first dielectric material in a cross-sectional view.

18. The device package of claim 17, further comprising:
a second conductive line extending laterally from the first bond pad and located over the first semiconductor die apart from the first and second dielectric materials, wherein the first conductive line has a greater width than the second conductive line.

19. The device package of claim 16, further comprising:
a second metal feature disposed between the first and second dielectric materials, the second metal feature being electrically coupled to the first and second bond pads, wherein the first semiconductor die has a third bond pad, and a distance between the first and second metal features is greater than a distance between the first and third bond pads.

20. The device package of claim 16, wherein the first metal feature has a rectangular profile in a top view, and the first bond pad has a circular profile in the top view.
